(19) United States
(12) Patent Application Publication
(10) Pub. No.: US 2026/0057932 A1
(43) Pub. Date: Feb. 26, 2026

(54) MEMORY DEVICE WITH NORMAL AND TRANSPOSED MEMORY ACCESS

(71) Applicant: Taiwan Semiconductor Manufacturing Company, Ltd., Hsinchu (TW)

(72) Inventor: Masaru HARAGUCHI, Hsinchu (TW)

(21) Appl. No.: 18/812,676

(22) Filed: Aug. 22, 2024

(51) Int. Cl. G11C 11/419; G11C 11/412; G11C 11/418

(52) U.S. Cl. CPC G11C 11/419; G11C 11/412; G11C 11/418

(57) ABSTRACT

A device including a memory array configured to store data in memory cells, read circuits configured to read the data out of the memory cells, and a plurality of input/output (I/O) terminals. A first plurality of multiplexers is configured to retrieve the data out of the memory cells and transmit the data to the plurality of I/O terminals in a first sequence of rows of data, and a second plurality of multiplexers is configured to retrieve the data out of the memory cells and transmit the data to the plurality of I/O terminals in a second sequence of columns of data that are transposed from the first sequence of rows of data.

### BACKGROUND

Memory devices store information in memory, such as random-access memory (RAM). Memory devices can include compute-in-memory (CIM) systems and methods that store information in memory, such as RAM, and perform calculations in the memory device, as opposed to moving data between the memory device and another device for various computational steps. In CIM systems and methods, the stored data is accessed more quickly from the memory device than from other storage devices. Also, the stored data is analyzed more quickly in the memory device, which enables faster calculations in artificial intelligence (AI) applications, such as large language models (LLMs) and convolutional neural networks (CNNs).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a memory device configured for row-wise and column-wise access of data from a memory array, in accordance with some embodiments.

FIG. 2 is a diagram schematically illustrating an SRAM memory array electrically coupled to the memory device circuits, in accordance with some embodiments.

FIG. 3 is a diagram schematically illustrating an example of a memory device that includes control circuits for row-wise access operations and for column-wise access operations of data from a memory array in the memory device, in accordance with some embodiments.

FIG. 4 is a diagram schematically illustrating an SRAM cell that can be used in the memory devices of FIGS. 1 and 3, in accordance with some embodiments.

FIG. 5 is a diagram schematically illustrating control circuits connected to a memory array, in accordance with some embodiments.

FIG. 6 is a diagram schematically illustrating the multiplexers and the I/O terminals, in accordance with some embodiments.

FIG. 7 is a diagram schematically illustrating a write operation of the memory array by the control circuits, in accordance with some embodiments.

FIG. 8 is a diagram schematically illustrating an external data map of the data that is written into the memory array, in accordance with some embodiments.

FIG. 9 is a diagram schematically illustrating a “normal” row-wise read operation of the memory array by the control circuits, in accordance with some embodiments.

FIG. 10 is a diagram schematically illustrating a “transposed” column-wise read operation of the memory array by the control circuits, in accordance with some embodiments.

FIG. 11 is a diagram schematically illustrating an external data map of the data that is read from the memory array, in accordance with some embodiments.

FIG. 12 is a diagram schematically illustrating control circuits connected to a memory array that includes a first memory bank (Bank 0) and a second memory bank (Bank 1), in accordance with some embodiments.

FIG. 13 is a diagram schematically illustrating an external data map of data read from the first memory bank and the second memory bank in “transposed” column-wise read operations, in accordance with some embodiments.

FIG. 14 is a diagram schematically illustrating a method of operating a memory device, in accordance with some embodiments.

FIG. 15 is a block diagram schematically illustrating an example of a computer system configured to provide the electronic devices, semiconductor devices, and methods of the current disclosure, in accordance with some embodiments.

FIG. 16 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Often, in AI applications, data is read from the memory and rearranged prior to performing calculations, such as matrix calculations. Sometimes, extra buffers are included for this purpose, such as dedicated buffers for row-wise access and column-wise access and multiple macros for rearranging the data. This has a negative effect on energy efficiency, where power and latency are increased, as well as increasing the size of the device.

Disclosed embodiments provide a memory device configured to provide 2 ways of accessing data stored in the memory. In a first operation, the data is read out of the memory in a “normal” row-wise sequence of data from the memory. In a second operation, the data is read out of the memory in a “transposed” column-wise sequence of data from the memory. With this, the memory device is adaptive to different matrix computations, such as for AI applications.

Disclosed embodiments further provide a device that includes a first plurality of multiplexers that retrieve data out of memory cells and transmit the data to a plurality of input/output (I/O) terminals in a first sequence of rows of data, and a second plurality of multiplexers that retrieve the data out of the memory cells and transmit the data to the plurality of I/O terminals in a second sequence of columns of data that are transposed from the first sequence of rows of data.

Disclosed embodiments still further provide a method of operating a memory device that includes storing data in memory cells of a memory array, reading, by read circuits, the data out of the memory cells, and selecting a first plurality of multiplexers or a second plurality of multiplexers. If the first plurality of multiplexers is selected the method includes retrieving the data out of the memory cells and transmitting the data to a plurality of I/O terminals in a first sequence of rows of data. If the second plurality of multiplexers is selected the method includes retrieving the data out of the memory cells and transmitting the data to the plurality of I/O terminals in a second sequence of columns of data that are transposed from the first sequence of the rows of data.

Advantages of the disclosed embodiments include that data rearrangement is achieved by the memory device and without extra buffers or multiple macros. Also, the disclosed embodiments provide gains by reducing power, reducing latency, and reducing the area or size of the memory device.

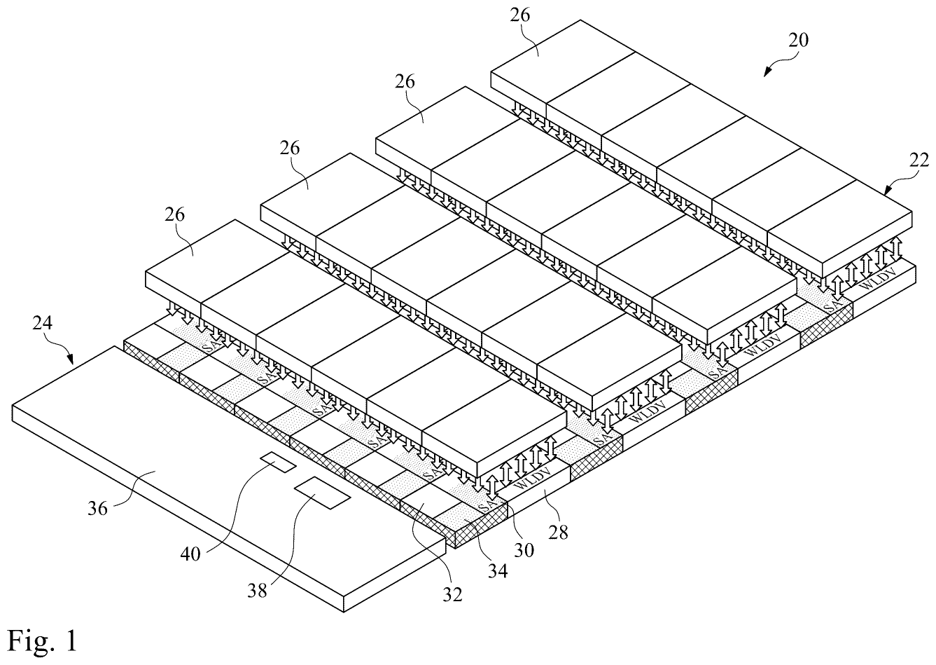

FIG. 1 is a diagram schematically illustrating a memory device 20 configured for row-wise and column-wise access of data from a memory array 22, in accordance with some embodiments. In a first access operation, the data is read out of the memory array 22 in a “normal” row-wise sequence of the data. In a second access operation, the data is read out of the memory array 22 in a “transposed” column-wise sequence of the data. The memory device 20 can be an electronic device, one or more semiconductor devices, and/or one or more integrated circuit devices.

The memory device 20 includes the memory array 22 situated above or on top of memory device circuits 24. In some embodiments, the memory device 20 is a CIM device that includes the memory device circuits 24 configured to provide functions for applications, such as LLM applications and/or CNN applications. In some embodiments, the memory device 20 includes the memory array 22 that is a back-end-of-line (BEOL) memory array situated above the memory device circuits 24 that are front-end-of-line (FEOL) circuits. In other embodiments, the memory array 22 can be situated on the same level or below/underneath the memory device circuits 24.

The memory array 22 is a static random-access memory (SRAM) array including multiple SRAM memory arrays 26. In other embodiments, the memory array 22 can be a different type of memory array, such as an RRAM array, an MRAM array, or a PCRAM array. In still other embodiments, the memory array 22 can be a dynamic random-access memory (DRAM) array.

The memory device circuits 24 include word line drivers (WLDVs) 28, column multiplexers and sense amplifiers (CMSAs) 30, column select (CS) circuits 32, read circuits 34, and CIM circuits 36. The WLDVs 28 and the CMSAs 30 are situated directly under the SRAM memory arrays 26 and electrically coupled to the SRAM memory arrays 26. The CS circuits 32, which include column decoder circuits, and the read circuits 34 are situated between the footprints of the SRAM memory arrays 26 and electrically coupled to the CMSAs 30. Each of the read circuits 34 includes a read port electrically coupled to the CIM circuits 36 that are configured to receive data from the read ports. In some embodiments, the read circuits 34 include I/O terminals or ports, input multiplexers, and/or output multiplexers.

The CIM circuits 36 include circuits that perform functions of supported applications, such as LLM applications and/or CNN applications. In some embodiments, the CIM circuits 36 include weight buffer circuits 38 and MAC circuits 40 configured to provide accumulated results. In some embodiments, the CIM circuits 36 perform functions of an LLM. In some embodiments, the CIM circuits 36 perform functions of a CNN.

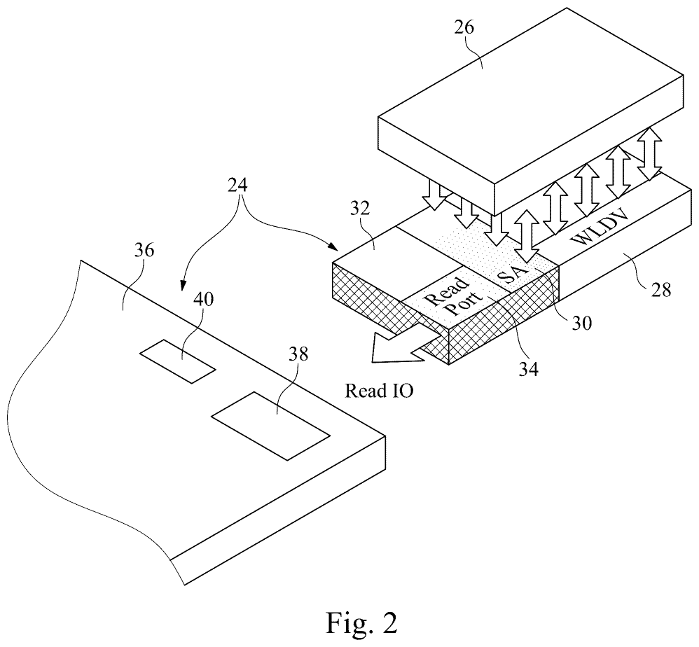

FIG. 2 is a diagram schematically illustrating an SRAM memory array 26 electrically coupled to the memory device circuits 24, in accordance with some embodiments. The memory device circuits 24 include the WLDVs 28 and the CMSAs 30 situated directly underneath and electrically coupled to the SRAM memory array 26. Also, the memory device circuits 24 include the CS circuits 32 and the read circuits 34 electrically coupled to the CMSAs 30 and situated adjacent a footprint of the SRAM memory array 26. In addition, the memory device circuits 24 include the CIM circuits 36, such as the weight buffer circuits 38 and the MAC circuits 40.

During a read operation, the WLDVs 28 and the CS circuits 32 provide signals for reading the SRAM memory array 26. The CMSAs 30 select columns of bit lines (BLs) and bit line bars (BLBs) and sense the voltages from memory cells in the SRAM memory array 26. The read circuit 34 obtains voltages from the CMSAs 30 that correspond to the voltages sensed from the memory cells in the SRAM memory array 26. The read circuit 34 outputs voltages at the read port that correspond to the voltages read from the CMSAs 30 by the read circuit 34. The CIM circuits 36 receive the output voltages from the read port and perform functions of the memory device 20, such as functions for an LLM application and/or functions for a CNN application. In some embodiments, the read port provides output voltages to output multiplexers. In some embodiments, the read port provides output voltages to output multiplexers that provide the voltages to the CIM circuits 36.

During a write operation, the WLDVs 28 and the CS circuits 32 provide signals for writing the SRAM memory array 26. The CMSAs 30 receive input data, such as through input multiplexers and I/O ports, that are written into the SRAM memory array 26. In some embodiments, the input multiplexers and the I/O ports are part of the read circuits 34.

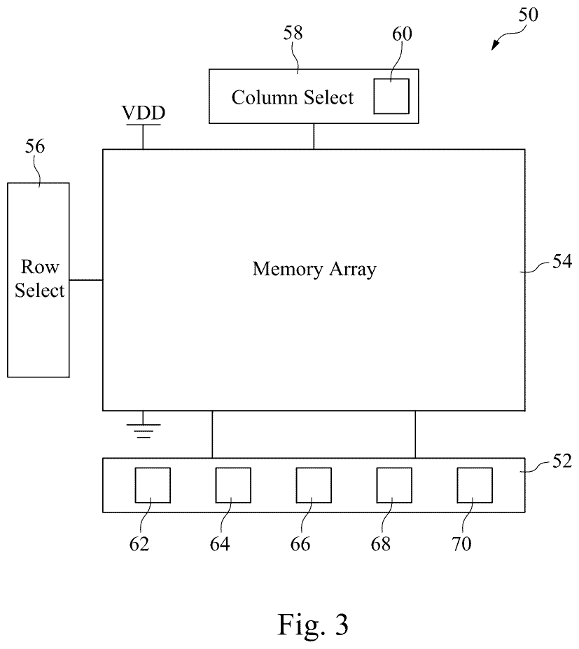

FIG. 3 is a diagram schematically illustrating an example of a memory device 50 that includes control circuits 52 for row-wise access operations and for column-wise access operations on data from a memory array 54 in the memory device 50, in accordance with some embodiments. In a first access operation, the data is read out of the memory array 54 in the “normal” row-wise sequence of the data. In a second access operation, the data is read out of the memory array 54 in the “transposed” column-wise sequence of the data. In some embodiments, the memory device 50 is like the memory device 20 of FIG. 1. In some embodiments, the memory device 50 includes the CIM circuits 36, shown in FIGS. 1 and 2, that are configured to provide functions for AI applications, such as LLM applications and/or CNN applications. In some embodiments, the memory array 54 is a BEOL memory array situated above CIM circuits that are FEOL circuits.

The memory array 54 includes a plurality of memory cells that store data. The memory array 54 and associated circuits are connected between a power terminal that receives a VDD voltage and a ground terminal. A row select circuit 56 and a column select circuit 58 are connected to the memory array 54 and configured to select memory cells in rows and columns of the memory array 54 during read and write operations. In some embodiments, the row select circuit 56 includes the WLDVs 28, shown in FIGS. 1 and 2. In some embodiments, the column select circuit 58 is like the CS circuits 32, shown in FIGS. 1 and 2. In some embodiments, the column select circuit 58 includes one or more column decoder circuits 60 for selecting columns while reading data in the normal row-wise sequence of the data and reading data in the transposed column-wise sequence of the data.

The control circuits 52 are connected to the memory array 54, such as to BLs and BLBs, and configured to write data into the memory array 54 and read data out of the memory array 54. The control circuits 52 include a first plurality of multiplexers 62 that retrieve data out of the memory array 54 and transmit the data to a plurality of I/O terminals 64 in a first sequence of rows of data, and a second plurality of multiplexers 66 that retrieve the data out of the memory array 54 and transmit the data to the plurality of I/O terminals 64 in a second sequence of columns of data that is transposed from the first sequence of rows of data. In some embodiments, the control circuits 52 include input multiplexers 68 and/or output multiplexers 70. In some embodiments, the control circuits 52 include the WLDVs 28, the CMSAs 30, and the read circuits 34, shown in FIGS. 1 and 2.

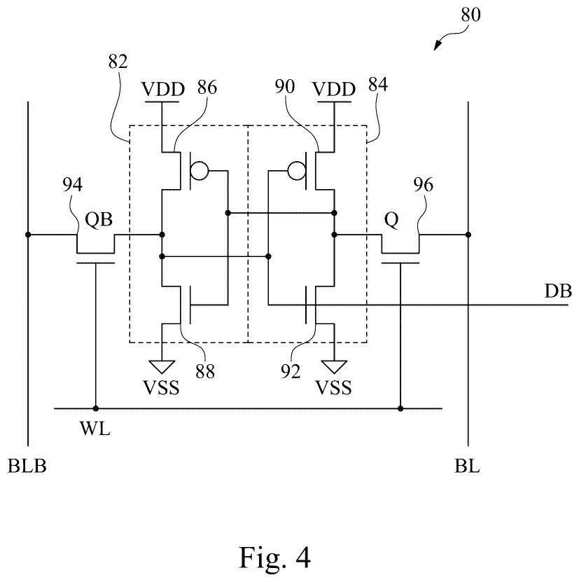

FIG. 4 is a diagram schematically illustrating an SRAM cell 80 that can be used in the memory devices of FIGS. 1 and 3, in accordance with some embodiments. The SRAM cell 80 is a six-transistor (6T) SRAM cell. In some embodiments, the SRAM cell 80 is used in the memory device 20 of FIG. 1. In some embodiments, the SRAM cell 80 is used in the memory device 50 of FIG. 3. In some embodiments, the SRAM cell 80 is used in the memory array 54 shown in FIG. 3. In other embodiments, the SRAM cell 80 can include more or fewer than six transistors, such as four, eight, or ten transistors.

The SRAM cell 80 includes two cross-coupled inverters 82 and 84. The first inverter 82 includes a first PMOS/NMOS transistor pair 86 and 88, and the second inverter 84 includes a second PMOS/NMOS transistor pair 90 and 92. The SRAM cell 80 further includes a left pass gate transistor 94 and a right pass gate transistor 96.

Power is supplied to each of the inverters 82 and 84, where a first terminal of each of a left pull-up transistor 86 and a right pull-up transistor 90 is electrically coupled to a power supply VDD, and a first terminal of each of a left pull-down transistor 88 and a right pull-down transistor 92 is electrically coupled to a reference voltage VSS, such as ground. A bit of data is stored in the SRAM cell 80 as a voltage at node Q and can be read through the right pass gate transistor 96 via the bit line BL, where access to the node Q is controlled by the right pass gate transistor 96. The node Q bar (QB) stores the complement of the value at node Q, such that if Q is high then QB is low and vice-versa. The node QB can be read through the left pass gate transistor 94 via the bit line bar BLB, where access to the node QB is controlled by the left pass gate transistor 94.

A gate of the left pass gate transistor 94 is coupled to a word line WL. A first source/drain (S/D) terminal of the left pass gate transistor 94 is coupled to the bit line bar BLB, and a second S/D terminal of the left pass gate transistor 94 is coupled to the second terminals of the left pull-up transistor 86 and the left pull-down transistor 88 at the node QB and to the gates of the right pull-up transistor 90 and the right pull-down transistor 92.

Also, a gate of the right pass gate transistor 96 is coupled to the word line WL. A first S/D terminal of the right pass gate transistor 96 is coupled to the bit line BL, and a second S/D terminal of the right pass gate transistor 96 is coupled to second terminals of right pull-up transistor 90 and right pull-down transistor 92 at the node Q and to the gates of the left pull-up transistor 86 and the left pull-down transistor 88.

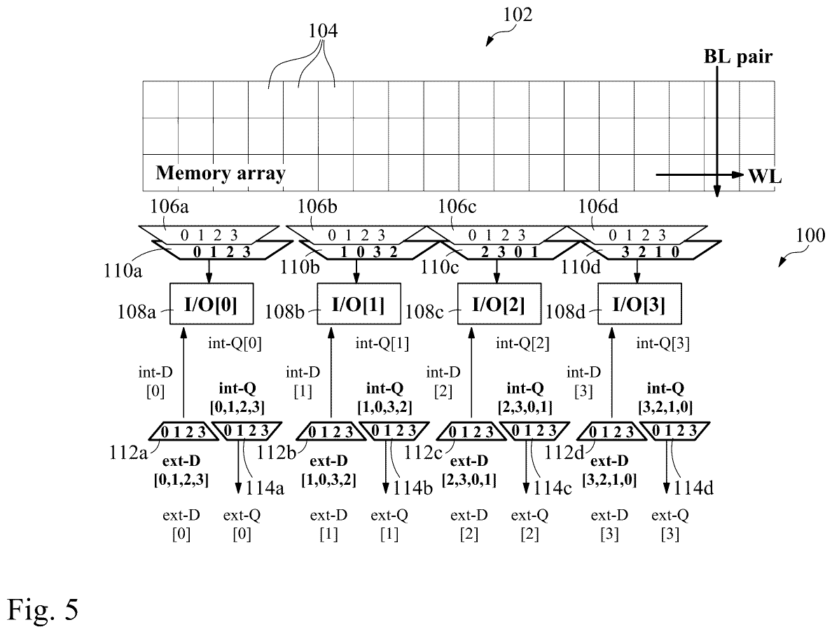

FIG. 5 is a diagram schematically illustrating control circuits 100 connected to a memory array 102, in accordance with some embodiments. The control circuits 100 are configured to provide row-wise access operations and column-wise access operations on data in the memory array 102. In a first access operation, the data is read out of the memory array 102 in the “normal” row-wise sequence of the data. In a second access operation, the data is read out of the memory array 102 in the “transposed” column-wise sequence of the data. In some embodiments, the control circuits 100 are like the control circuits 52 shown in FIG. 3. In some embodiments, the memory array 102 is like the memory array 54 shown in FIG. 3.

The memory array 102 includes a plurality of memory cells 104 that store data. The memory array 102 includes BL pairs of BLs and WLs for accessing the memory cells 104 in the memory array 102. Also, row select circuits, such as row select circuit 56, and column select circuits, such as column select circuit 58, are connected to the memory array 102 and configured to select memory cells 104 in rows and columns of the memory array 102 during read and write operations. In some embodiments, the column select circuit includes one or more column decoder circuits, such as column decoder circuits 60, for selecting columns while reading data in the normal row-wise sequence of the data and the transposed column-wise sequence of the data. In some embodiments, the memory cells 104 are SRAM cells. In some embodiments, the memory cells 104 are like memory cell 80 of FIG. 4.

The control circuits 100 are connected to the memory array 102, such as by the BL pairs of BLs and BLBs, and configured to write data into the memory array 102 and read data out of the memory array 102. The control circuits 100 include a first plurality of multiplexers 106a-106d that retrieve data out of the memory array 102 and transmit the data to a plurality of I/O terminals 108a-108d in the first sequence of rows of data. Each of the first plurality of multiplexers 106a-106d is a 4 to 1 multiplexer having 4 inputs, such as 4 BL pair inputs (8 inputs), an output, and control inputs for selecting the input that is provided to the output of the multiplexer. The control circuits 100 include a second plurality of multiplexers 110a-110d that retrieve the data out of the memory array 102 and transmit the data to the plurality of I/O terminals 108a-108d in the second sequence of columns of data that is transposed from the first sequence of rows of data. Each of the second plurality of multiplexers 110a-110d is a 4 to 1 multiplexer having 4 inputs, such as 4 BL pair inputs (8 inputs), an output, and control inputs for selecting the input that is provided to the output of the multiplexer. In some embodiments, the first plurality of multiplexers 106a-106d is like the first plurality of multiplexers 62 shown in FIG. 3. In some embodiments, the second plurality of multiplexers 110a-110d is like the second plurality of multiplexers 66 shown in FIG. 3. In some embodiments, the plurality of I/O terminals 108a-108d is like the plurality of I/O terminals 64 shown in FIG. 3. In other embodiments, each of the first plurality of multiplexers 106a-106d has more than 4 inputs, such as 8 or 16 inputs and one output. Also, in other embodiments, each of the second plurality of multiplexers 110a-110d has more than 4 inputs, such as 8 or 16 inputs and one output.

The control circuits 100 include a plurality of input multiplexers 112a-112d that receive data and transmit the data to the plurality of I/O terminals 108a-108d. Each of the plurality of input multiplexers 112a-112d is a 4 to 1 multiplexer having 4 inputs, an output, and control inputs for selecting the input that is provided to the output of the multiplexer. Also, the control circuits 100 include a plurality of output multiplexers 114a-114d that receive the data from the plurality of I/O terminals 108a-108d and output the data to other hardware, such as hardware that is external to the control circuits 100 and/or the memory device. Each of the plurality of output multiplexers 114a-114d is a 4 to 1 multiplexer having 4 inputs, an output, and control inputs for selecting the input that is provided to the output of the multiplexer. In some embodiments, the plurality of input multiplexers 112a-112d are like the input multiplexers 68 shown in FIG. 3. In some embodiments, the plurality of output multiplexers 114a-114d are like the output multiplexers 70 shown in FIG. 3. In other embodiments, each of the plurality of input multiplexers 112a-112d has more than 4 inputs, such as 8 or 16 inputs and one output. Also, in other embodiments, each of the plurality of output multiplexers 114a-114d has more than 4 inputs, such as 8 or 16 inputs and one output. In other embodiments, the plurality of input multiplexers 112a-112d and/or the plurality of output multiplexers 114a-114d are external to the control circuits 100.

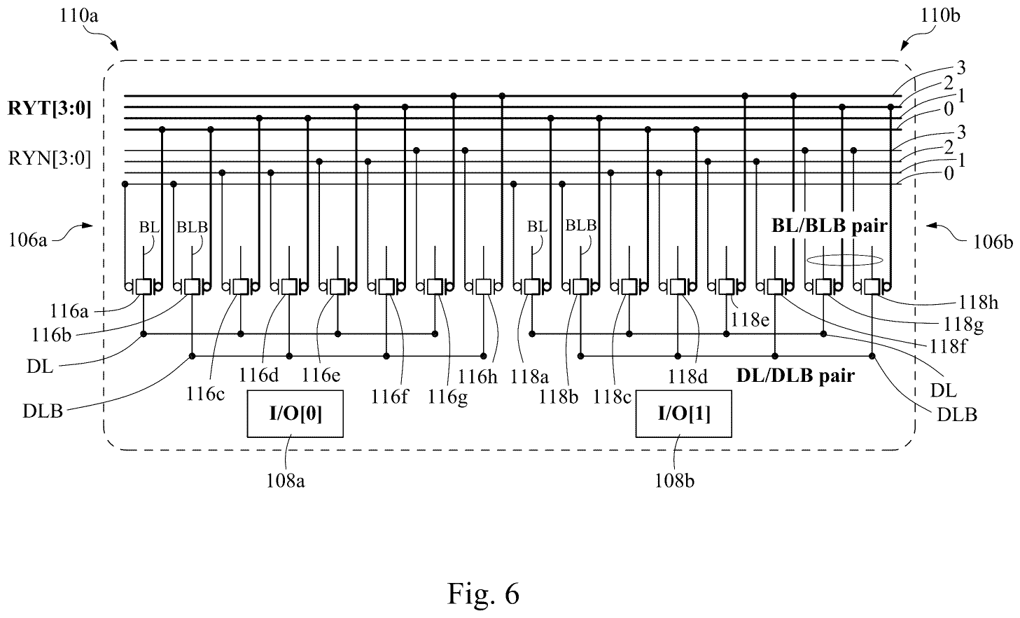

FIG. 6 is a diagram schematically illustrating the multiplexers 106a, 106b, 110a, and 110b and the I/O terminals 108a and 108b, in accordance with some embodiments. The multiplexers 106a and 106b are examples of the multiplexers in the first plurality of multiplexers 106a-106d and the multiplexers 110a and 110b are examples of the multiplexers in the second plurality of multiplexers 110a-110d. The other multiplexers in the first plurality of multiplexers 106a-106d and the second plurality of multiplexers 110a-110d will not be further described herein.

The multiplexers 106a and 110a include PMOS transistor pass gates 116a-116h. Each of the PMOS transistor pass gates 116a-116h includes two PMOS transistors having their drains connected to each other and their sources connected to each other. One of the drain connections or the source connections is connected to a BL or a BLB and the other one of the drain connections or the source connections is connected to a data line (DL) or a data line bar (DLB). Also, one gate of the two PMOS transistors is connected to one of the normal column select lines RYN[3:0] for the multiplexer 106a and another gate of the two PMOS transistors is connected to the transposed column select lines RYT[3:0] for the multiplexer 110a.

The PMOS transistor pass gates 116a, 116c, 116e, and 116g are connected to the BLs and the PMOS transistor pass gates 116b, 116d, 116f, and 116h are connected to the BLBs. Also, the PMOS transistor pass gates 116a, 116c, 116e, and 116g are connected to the DLs that are connected to each other at the output of the multiplexers 106a and 110a, and the PMOS transistor pass gates 116b, 116d, 116f, and 116h are connected to the DLBs that are connected to each other at the output of the multiplexers 106a and 110a.

The normal column select lines RYN[3:0] for the multiplexer 106a are connected to one PMOS transistor in each of the PMOS transistor pass gates 116a-116h and the transposed column select lines RYT[3:0] for the multiplexer 110a are connected to the other PMOS transistor in each of the PMOS transistor pass gates 116a-116h.

The multiplexer 106a is connected to the normal column select lines RYN[3:0] in a [0,1,2,3] sequence of the normal column select lines RYN[3:0]. Pass gate 116a is connected to a first address line 0 of the normal column select lines RYN[3:0] for BL and DL and pass gate 116b is connected to the first address line 0 of the normal column select lines RYN[3:0] for BLB and DLB. Pass gate 116c is connected to a second address line 1 of the normal column select lines RYN[3:0] for BL and DL and pass gate 116d is connected to the second address line 1 of the normal column select lines RYN[3:0] for BLB and DLB. Pass gate 116e is connected to a third address line 2 of the normal column select lines RYN[3:0] for BL and DL and pass gate 116f is connected to the third address line 2 of the normal column select lines RYN[3:0] for BLB and DLB. Pass gate 116g is connected to a fourth address line 3 of the normal column select lines RYN[3:0] for BL and DL and pass gate 116h is connected to the fourth address line 3 of the normal column select lines RYN[3:0] for BLB and DLB.

The multiplexer 110a is connected to the transposed column select lines RYT[3:0] in a [0,1,2,3] sequence of the transposed column select lines RYT[3:0]. Pass gate 116a is connected to a first address line 0 of the transposed column select lines RYT[3:0] for BL and DL and pass gate 116b is connected to the first address line 0 of the transposed column select lines RYT[3:0] for BLB and DLB. Pass gate 116c is connected to a second address line 1 of the transposed column select lines RYT[3:0] for BL and DL and pass gate 116d is connected to the second address line 1 of the transposed column select lines RYT[3:0] for BLB and DLB. Pass gate 116e is connected to a third address line 2 of the transposed column select lines RYT[3:0] for BL and DL and pass gate 116f is connected to the third address line 2 of the transposed column select lines RYT[3:0] for BLB and DLB. Pass gate 116g is connected to a fourth address line 3 of the transposed column select lines RYT[3:0] for BL and DL and pass gate 116h is connected to the fourth address line 3 of the transposed column select lines RYT[3:0] for BLB and DLB.

The multiplexers 106b and 110b include PMOS transistor pass gates 118a-118h. Each of the PMOS transistor pass gates 118a-118h includes two PMOS transistors having their drains connected to each other and their sources connected to each other. One of the drain connections or the source connections is connected to a BL or a BLB and the other one of the drain connections or the source connections is connected to a DL or a DLB. Also, one gate of the two PMOS transistors is connected to one of the normal column select lines RYN[3:0] for the multiplexer 106b and another gate of the two PMOS transistors is connected to the transposed column select lines RYT[3:0] for the multiplexer 110b.

The PMOS transistor pass gates 118a, 118c, 118e, and 118g are connected to the BLs and the PMOS transistor pass gates 118b, 118d, 118f, and 118h are connected to the BLBs. Also, the PMOS transistor pass gates 118a, 118c, 118e, and 118g are connected to the DLs that are connected to each other at the output of the multiplexers 106b and 110b, and the PMOS transistor pass gates 118b, 118d, 118f, and 118h are connected to the DLBs that are connected to each other at the output of the multiplexers 106b and 110b.

The normal column select lines RYN[3:0] for the multiplexer 106b are connected to one PMOS transistor in each of the PMOS transistor pass gates 118a-118h and the transposed column select lines RYT[3:0] for the multiplexer 110b are connected to the other PMOS transistor in each of the PMOS transistor pass gates 118a-118h.

The multiplexer 106b is connected to the normal column select lines RYN[3:0] in a [0,1,2,3] sequence of the normal column select lines RYN[3:0]. Pass gate 118a is connected to a first address line 0 of the normal column select lines RYN[3:0] for BL and DL and pass gate 118b is connected to the first address line 0 of the normal column select lines RYN[3:0] for BLB and DLB. Pass gate 118c is connected to a second address line 1 of the normal column select lines RYN[3:0] for BL and DL and pass gate 118d is connected to the second address line 1 of the normal column select lines RYN[3:0] for BLB and DLB. Pass gate 118e is connected to a third address line 2 of the normal column select lines RYN[3:0] for BL and DL and pass gate 118f is connected to the third address line 2 of the normal column select lines RYN[3:0] for BLB and DLB. Pass gate 118g is connected to a fourth address line 3 of the normal column select lines RYN[3:0] for BL and DL and pass gate 118h is connected to the fourth address line 3 of the normal column select lines RYN[3:0] for BLB and DLB.

The multiplexer 110b is connected to the transposed column select lines RYT[3:0] in a [1,0,3,2] sequence of the transposed column select lines RYT[3:0]. Pass gate 118a is connected to a second address line 1 of the transposed column select lines RYT[3:0] for BL and DL and pass gate 118b is connected to the second address line 1 of the transposed column select lines RYT[3:0] for BLB and DLB. Pass gate 118c is connected to a first address line 0 of the transposed column select RYT[3:0] for BL and DL and pass gate 118d is connected to the first address line 0 of the transposed column select lines RYT[3:0] for BLB and DLB. Pass gate 118e is connected to a fourth address line 3 of the transposed column select lines RYT[3:0] for BL and DL and pass gate 118f is connected to the fourth address line 3 of the transposed column select lines RYT[3:0] for BLB and DLB. Pass gate 118g is connected to third address line 2 of the transposed column select lines RYT[3:0] for BL and DL and pass gate 118h is connected to the third address line 2 of the transposed column select lines RYT[3:0] for BLB and DLB.

In further reference to FIGS. 5 and 6, each of the multiplexers 106a-106d is connected to the normal column select lines RYN[3:0] in a [0,1,2,3] sequence of the normal column select lines RYN[3:0]. The multiplexer 110a is connected to the transposed column select lines RYT[3:0] in a [0,1,2,3] sequence of the transposed column select lines RYT[3:0], the multiplexer 110b is connected to the transposed column select lines RYT[3:0] in a [1,0,3,2] sequence of the transposed column select lines RYT[3:0], the multiplexer 110c is connected to the transposed column select lines RYT[3:0] in a [2,3,0,1] sequence of the transposed column select lines RYT[3:0], and the multiplexer 110d is connected to the transposed column select lines RYT[3:0] in a [3,2,1,0] sequence of the transposed column select lines RYT[3:0]. In some embodiments, the column select circuit 58 provides select signals for the normal column select lines RYN[3:0] and the transposed column select lines RYT[3:0]. In some embodiments, the decoder circuit 60 selects whether the normal column select lines RYN[3:0] or the transposed column select lines RYT[3:0] are activated.

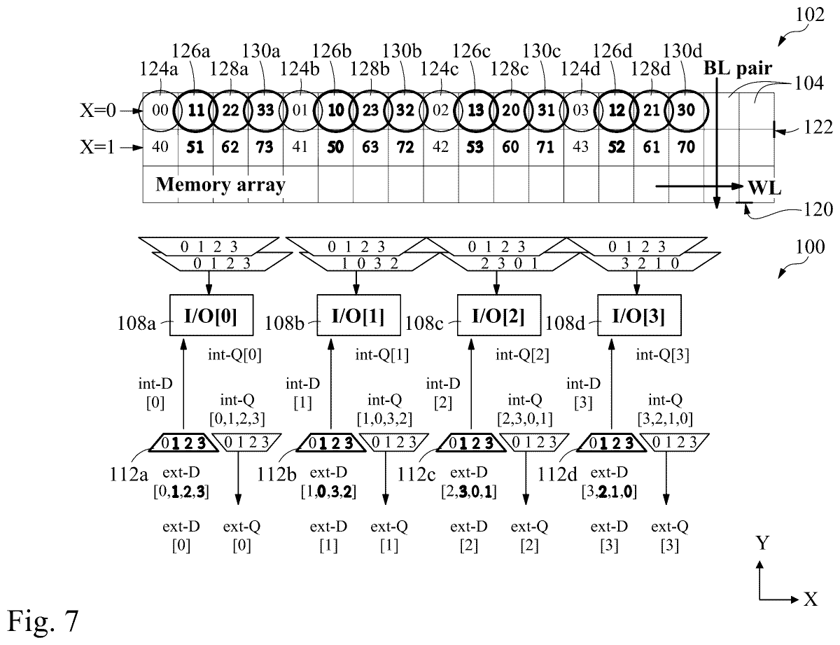

FIG. 7 is a diagram schematically illustrating a write operation of the memory array 102 by the control circuits 100, in accordance with some embodiments. The memory array 102 includes the plurality of memory cells 104 situated in rows along the x-axis 120 and columns along the y-axis 122. A row select circuit, such as the row select circuit 56, and a column select circuit, such as the column select circuit 58, decode addresses and select the rows and the columns of the memory cells to be written. In some embodiments, the column select circuit includes one or more column decoder circuits, such as the column decoder circuits 60, for selecting inputs of the plurality of input multiplexers 112a-112d for writing data into the memory array 102.

The control circuits 100 include the plurality of input multiplexers 112a-112d that receive data and transmit the data to the plurality of I/O terminals 108a-108d. Each of the plurality of input multiplexers 112a-112d is a 4 to 1 multiplexer having 4 inputs, an output, and control inputs (not shown) for selecting the input that is provided to the output of the multiplexer. In some embodiments, the plurality of input multiplexers 112a-112d are like the input multiplexers 68 shown in FIG. 3. In other embodiments, each of the plurality of input multiplexers 112a-112d has more than 4 inputs, such as 8 or 16 inputs and one output.

To write data into the memory array 102, data is transmitted to each of the external data inputs ext-D[0], ext-D[1], ext-D[2], and ext-D[3] and passed through a corresponding one of the plurality of input multiplexers 112a-112d to internal data inputs int-D[0], int-D[1], int-D[2], and int-D[3] and the plurality of I/O terminals 108a-108d, respectively. Each of the four inputs on each of the plurality of input multiplexers 112a-112d receives data. Input multiplexer 112a receives ext-D [0,1,2,3], input multiplexer 112b receives ext-D[1,0,3,2], input multiplexer 112c receives ext-D [2,3,0,1], and input multiplexer 112d receives ext-D [3,2,1,0].

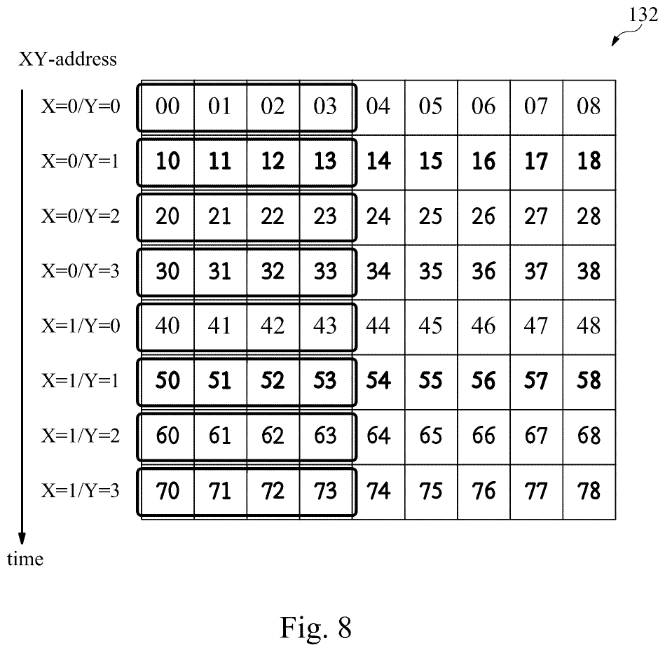

The data that is written into the memory array 102 is provided externally, such as by another device or by a user. FIG. 8 is a diagram schematically illustrating an external data map 132 of the data that is written into the memory array 102, in accordance with some embodiments.

In a write operation, the row select circuit selects a row, such as x=0, and the column select circuit or one of the column decoder circuits selects a column, such as y=0, 1, 2, or 3. The selected column of y=0, 1, 2, or 3 selects one of the 4 inputs on each of the plurality of input multiplexers 112a-112d, which is provided to the output of the multiplexer. The inputs of each of the plurality of input multiplexers 112a-112d are selected in the order [0,1,2,3] and all the plurality of input multiplexers 112a-112d receive the same column select signal.

In reference to FIGS. 7 and 8, with the x-y address of the memory array 102 at x=0 and y=0, the data 00 is provided to the external data input ext-D[0] and written into memory cell 124a through the input multiplexer 112a and the I/O terminal 108a, the data 01 is provided to the external data input ext-D[1] and written into memory cell 124b through the input multiplexer 112b and the I/O terminal 108b, the data 02 is provided to the external data input ext-D[2] and written into memory cell 124c through the input multiplexer 112c and the I/O terminal 108c, and the data 03 is provided to the external data input ext-D[3] and written into the memory cell 124d through the input multiplexer 112d and the I/O terminal 108d.

With the x-y address of the memory array 102 at x=0 and y=1, the data 11 is provided to the external data input ext-D[0] and written into memory cell 126a through the input multiplexer 112a and the I/O terminal 108a, the data 10 is provided to the external data input ext-D[1] and written into memory cell 126b through the input multiplexer 112b and the I/O terminal 108b, the data 13 is provided to the external data input ext-D[2] and written into memory cell 126c through the input multiplexer 112c and the I/O terminal 108c, and the data 12 is provided to the external data input ext-D[3] and written into the memory cell 126d through the input multiplexer 112d and the I/O terminal 108d.

With the x-y address of the memory array 102 at x=0 and y=2, the data 22 is provided to the external data input ext-D[0] and written into memory cell 128a through the input multiplexer 112a and the I/O terminal 108a, the data 23 is provided to the external data input ext-D[1] and written into memory cell 128b through the input multiplexer 112b and the I/O terminal 108b, the data 20 is provided to the external data input ext-D[2] and written into memory cell 128c through the input multiplexer 112c and the I/O terminal 108c, and the data 21 is provided to the external data input ext-D[3] and written into the memory cell 128d through the input multiplexer 112d and the I/O terminal 108d.

With the x-y address of the memory array 102 at x=0 and y=3, the data 33 is provided to the external data input ext-D[0] and written into memory cell 130a through the input multiplexer 112a and the I/O terminal 108a, the data 32 is provided to the external data input ext-D[1] and written into memory cell 130b through the input multiplexer 112b and the I/O terminal 108b, the data 31 is provided to the external data input ext-D[2] and written into memory cell 130c through the input multiplexer 112c and the I/O terminal 108c, and the data 30 is provided to the external data input ext-D[3] and written into the memory cell 130d through the input multiplexer 112d and the I/O terminal 108d. This is repeated for any number of rows, such as row x=1 and columns y=0, 1, 2, and 3.

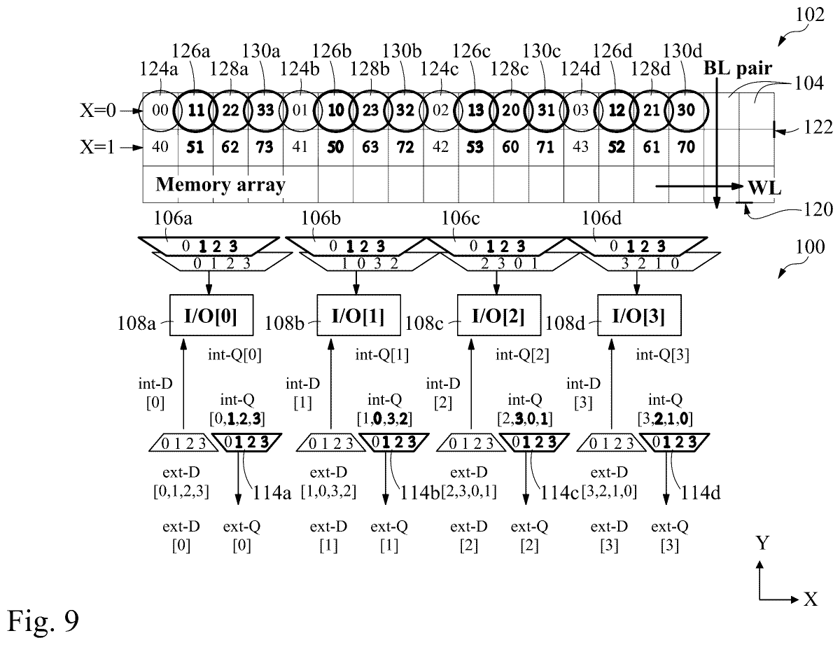

FIG. 9 is a diagram schematically illustrating a “normal” row-wise read operation of the memory array 102 by the control circuits 100, in accordance with some embodiments. The “normal” row-wise read operation reads data out of the memory array 102 in rows of data as shown in the external data map 132 of FIG. 8.

The memory array 102 includes the plurality of memory cells 104 situated in rows along the x-axis 120 and columns along the y-axis 122. A row select circuit, such as the row select circuit 56, and a column select circuit, such as the column select circuit 58, decode addresses and select the rows and the columns of the memory cells to be read. In some embodiments, the column select circuit includes one or more column decoder circuits, such as the column decoder circuits 60, for selecting inputs of the first plurality of multiplexers 106a-106d and inputs of the plurality of output multiplexers 114a-114d for reading data out of the memory array 102.

The control circuits 100 include the first plurality of multiplexers 106a-106d that receive data from the memory array 102 and transmit the data to the plurality of I/O terminals 108a-108d. Each of the first plurality of multiplexers 106a-106d is a 4 to 1 multiplexer having 4 inputs, an output, and control inputs (not shown) for selecting the input that is provided to the output of the multiplexer. The inputs of each of the first plurality of multiplexers 106a-106d are selected in a [0,1,2,3] sequence. In some embodiments, the first plurality of multiplexers 106a-106d is like the first plurality of multiplexers 62 shown in FIG. 3. In other embodiments, each of the first plurality of multiplexers 106a-106d has more than 4 inputs, such as 8 or 16 inputs, and one output.

The control circuits 100 further include the plurality of output multiplexers 114a-114d that receive data from the plurality of I/O terminals 108a-108d and the internal outputs int-Q. The plurality of output multiplexers 114a-114d transmit the data to the external outputs ext-Q. Each of the plurality of output multiplexers 114a-114d is a 4 to 1 multiplexer having 4 inputs, an output, and control inputs (not shown) for selecting the input that is provided to the output of the multiplexer. The inputs of each of the plurality of output multiplexers 114a-114d are selected in a [0,1,2,3] sequence. In some embodiments, the plurality of output multiplexers 114a-114d are like the output multiplexers 70 shown in FIG. 3. In other embodiments, each of the plurality of output multiplexers 114a-114d has more than 4 inputs, such as 8 or 16 inputs, and one output.

To read data out of the memory array 102, the first plurality of multiplexers 106a-106d receive data from the memory array 102 and transmit the data to the plurality of I/O terminals 108a-108d and the internal outputs int-Q[0], int-Q[1] int-Q[2], and int-Q[3]. Next, the data is passed through the plurality of output multiplexers 114a-114d to the external outputs ext-Q[0], ext-Q[1], ext-Q[2], and ext-Q[3]. Output multiplexer 114a receives internal output data int-Q [0,1,2,3], output multiplexer 114b receives internal output data int-Q [1,0,3,2], output multiplexer 114c receives internal output data int-Q [2,3,0,1], and output multiplexer 114d receives internal output data int-Q [3,2,1,0]. The data received at the external outputs ext-Q[0], ext-Q[1], ext-Q[2], and ext-Q[3] are mapped to the rows of the external data map 132, one row at a time.

In a read operation, the row select circuit selects a row, such as x=0, and the column select circuit or one of the column decoder circuits selects a column, such as y=0, 1, 2, or 3. The selected column of y=0, 1, 2, or 3 selects one of the 4 inputs on each of the first plurality of multiplexers 106a-106d and/or one of the 4 inputs on each of the plurality of output multiplexers 114a-114d. The inputs of each of the first plurality of multiplexers 106a-106dare selected in the order [0,1,2,3] and the inputs of each of the plurality of output multiplexers 114a-114d are selected in the order [0,1,2,3]. In some embodiments, all the first plurality of multiplexers 106a-106d receive the same column select signal. In some embodiments, all the plurality of output multiplexers 114a-114d receive the same column select signal. In some embodiments, all the first plurality of multiplexers 106a-106d and all the plurality of output multiplexers 114a-114d receive the same column select signal. In some embodiments, the first plurality of multiplexers 106a-106d and the plurality of output multiplexers 114a-114d receive different column select signals at different times.

In reference to FIGS. 8 and 9, with the x-y address of the memory array 102 at x=0 and y=0, the data 00 is read from the memory cell 124a, received by the multiplexer 106a, and transmitted to the I/O terminal I/O[0] 108a and the internal output int-Q[0]. The data 00 is further received by the output multiplexer 114a and transmitted to the external output ext-Q[0]. The data 01 is read from the memory cell 124b, received by the multiplexer 106b, and transmitted to the I/O terminal I/O[1] 108b and the internal output int-Q[1]. The data 01 is further received by the output multiplexer 114b and transmitted to the external output ext-Q[1]. The data 02 is read from the memory cell 124c, received by the multiplexer 106c, and transmitted to the I/O terminal I/O[2] 108c and the internal output int-Q[2]. The data 02 is further received by the output multiplexer 114c and transmitted to the external output ext-Q[2]. The data 03 is read from the memory cell 124d, received by the multiplexer 106d, and transmitted to the I/O terminal I/O[3] 108d and the internal output int-Q[3]. The data 03 is further received by the output multiplexer 114d and transmitted to the external output ext-Q[3]. The data received at the external outputs ext-Q[0], ext-Q[1], ext-Q[2], and ext-Q[3] are mapped to the first row of the external data map 132.

With the x-y address of the memory array 102 at x=0 and y=1, the data 11 is read from the memory cell 126a, received by the multiplexer 106a, and transmitted to the I/O terminal I/O[0] 108a and the internal output int-Q[0]. The data 11 is further received by the output multiplexer 114a and transmitted to the external output ext-Q[0]. The data 10 is read from the memory cell 126b, received by the multiplexer 106b, and transmitted to the I/O terminal I/O[1] 108b and the internal output int-Q[1]. The data 10 is further received by the output multiplexer 114b and transmitted to the external output ext-Q[1]. The data 13 is read from the memory cell 126c, received by the multiplexer 106c, and transmitted to the I/O terminal I/O[2] 108c and the internal output int-Q[2]. The data 13 is further received by the output multiplexer 114c and transmitted to the external output ext-Q[2]. The data 12 is read from the memory cell 126d, received by the multiplexer 106d, and transmitted to the I/O terminal I/O[3] 108d and the internal output int-Q[3]. The data 12 is further received by the output multiplexer 114d and transmitted to the external output ext-Q[3]. The data received at the external outputs ext-Q[0], ext-Q[1], ext-Q[2], and ext-Q[3] are mapped to the second row of the external data map 132.

With the x-y address of the memory array 102 at x=0 and y=2, the data 22 is read from the memory cell 128a, received by the multiplexer 106a, and transmitted to the I/O terminal I/O[0] 108a and the internal output int-Q[0]. The data 22 is further received by the output multiplexer 114a and transmitted to the external output ext-Q[0]. The data 23 is read from the memory cell 128b, received by the multiplexer 106b, and transmitted to the I/O terminal I/O[1] 108b and the internal output int-Q[1]. The data 23 is further received by the output multiplexer 114b and transmitted to the external output ext-Q[1]. The data 20 is read from the memory cell 128c, received by the multiplexer 106c, and transmitted to the I/O terminal I/O[2] 108c and the internal output int-Q[2]. The data 20 is further received by the output multiplexer 114c and transmitted to the external output ext-Q[2]. The data 21 is read from the memory cell 128d, received by the multiplexer 106d, and transmitted to the I/O terminal I/O[3] 108d and the internal output int-Q[3]. The data 21 is further received by the output multiplexer 114d and transmitted to the external output ext-Q[3]. The data received at the external outputs ext-Q[0], ext-Q[1], ext-Q[2], and ext-Q[3] are mapped to the third row of the external data map 132.

With the x-y address of the memory array 102 at x=0 and y=3, the data 33 is read from the memory cell 130a, received by the multiplexer 106a, and transmitted to the I/O terminal I/O[0] 108a and the internal output int-Q[0]. The data 33 is further received by the output multiplexer 114a and transmitted to the external output ext-Q[0]. The data 32 is read from the memory cell 130b, received by the multiplexer 106b, and transmitted to the I/O terminal I/O[1] 108b and the internal output int-Q[1]. The data 32 is further received by the output multiplexer 114b and transmitted to the external output ext-Q[1]. The data 31 is read from the memory cell 130c, received by the multiplexer 106c, and transmitted to the I/O terminal I/O[2] 108c and the internal output int-Q[2]. The data 31 is further received by the output multiplexer 114c and transmitted to the external output ext-Q[2]. The data 30 is read from the memory cell 130d, received by the multiplexer 106d, and transmitted to the I/O terminal I/O[3] 108d and the internal output int-Q[3]. The data 30 is further received by the output multiplexer 114d and transmitted to the external output ext-Q[3]. The data received at the external outputs ext-Q[0], ext-Q[1], ext-Q[2], and ext-Q[3] are mapped to the fourth row of the external data map 132.

This process is repeated for any number of rows, such as row x=1 and columns y=0, 1, 2, and 3.

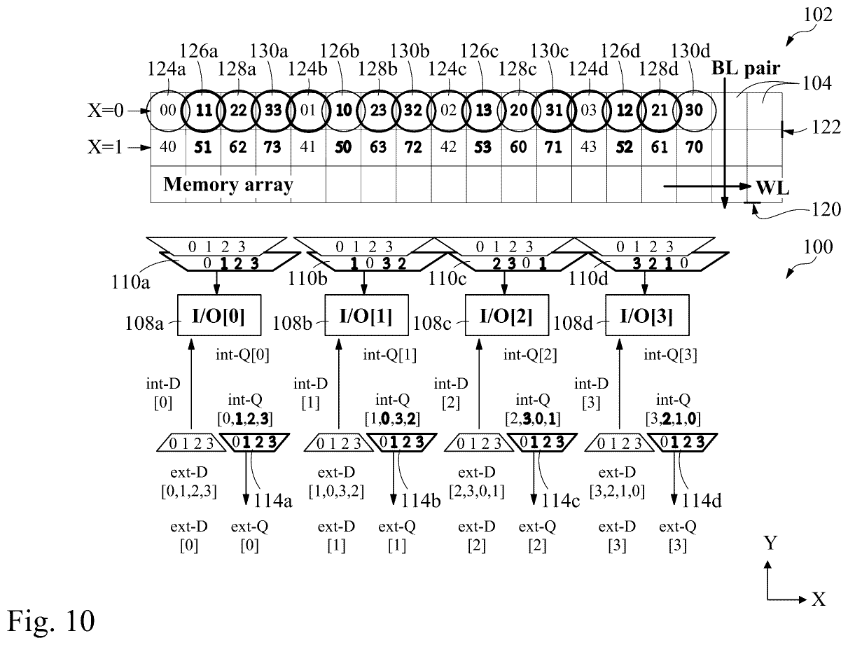

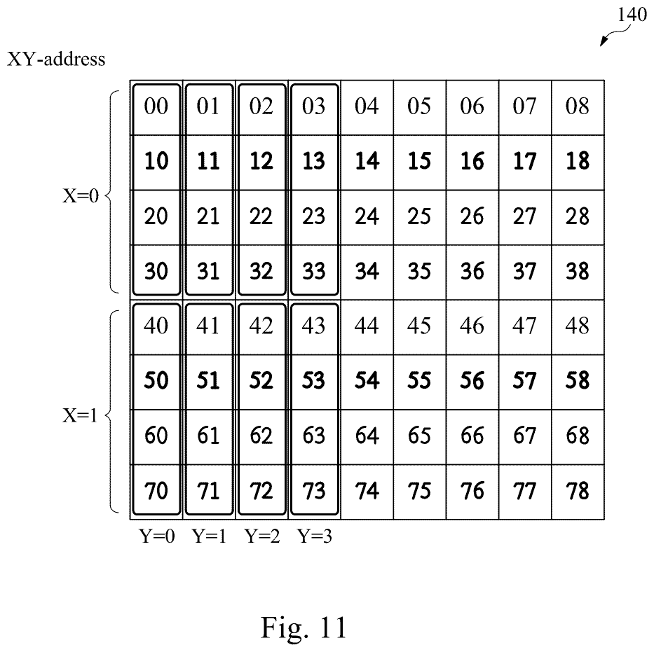

FIG. 10 is a diagram schematically illustrating a “transposed” column-wise read operation of the memory array 102 by the control circuits 100, in accordance with some embodiments, and FIG. 11 is a diagram schematically illustrating an external data map 140 of the data that is read from the memory array 102, in accordance with some embodiments. The “transposed” column-wise read operation reads data out of the memory array 102 in columns of data as shown in the external data map 140 of FIG. 11.

The memory array 102 includes the plurality of memory cells 104 situated in rows along the x-axis 120 and columns along the y-axis 122. A row select circuit, such as the row select circuit 56, and a column select circuit, such as the column select circuit 58, decode addresses and select the rows and the columns of the memory cells to be read. In some embodiments, the column select circuit includes one or more column decoder circuits, such as the column decoder circuits 60, for selecting inputs of the second plurality of multiplexers 110a-110d and inputs of the plurality of output multiplexers 114a-114d for reading data out of the memory array 102.

The control circuits 100 include the second plurality of multiplexers 110a-110d that receive data from the memory array 102 and transmit the data to the plurality of I/O terminals 108a-108d. Each of the second plurality of multiplexers 110a-110d is a 4 to 1 multiplexer having 4 inputs, an output, and control inputs (not shown) for selecting the input that is provided to the output of the multiplexer. The inputs of multiplexer 110a are selected in a [0,1,2,3] sequence, the inputs of multiplexer 110b are selected in a [1,0,3,2] sequence, the inputs of multiplexer 110c are selected in a [2,3,0,1] sequence, and the inputs of multiplexer 110d are selected in a [3,2,1,0] sequence. In some embodiments, the second plurality of multiplexers 110a-110d is like the second plurality of multiplexers 66 shown in FIG. 3. In other embodiments, each of the second plurality of multiplexers 110a-110d has more than 4 inputs, such as 8 or 16 inputs, and one output.

The control circuits 100 further include the plurality of output multiplexers 114a-114d that receive data from the plurality of I/O terminals 108a-108d and the internal outputs int-Q. The plurality of output multiplexers 114a-114d transmit the data to the external outputs ext-Q. Each of the plurality of output multiplexers 114a-114d is a 4 to 1 multiplexer having 4 inputs, an output, and control inputs (not shown) for selecting the input that is provided to the output of the multiplexer. The inputs of each of the plurality of output multiplexers 114a-114d are selected in a [0,1,2,3] sequence. In some embodiments, the plurality of output multiplexers 114a-114d are like the output multiplexers 70 shown in FIG. 3. In other embodiments, each of the plurality of output multiplexers 114a-114d has more than 4 inputs, such as 8 or 16 inputs, and one output.

To read data out of the memory array 102, the second plurality of multiplexers 110a-110d receive data from the memory array 102 and transmit the data to the plurality of I/O terminals 108a-108d and the internal outputs int-Q[0], int-Q[1] int-Q[2], and int-Q[3]. Next, the data is passed through the plurality of output multiplexers 114a-114d to the external outputs ext-Q[0], ext-Q[1], ext-Q[2], and ext-Q[3]. Output multiplexer 114a receives internal output data int-Q [0,1,2,3], output multiplexer 114b receives internal output data int-Q [1,0,3,2], output multiplexer 114c receives internal output data int-Q [2,3,0,1], and output multiplexer 114d receives internal output data int-Q [3,2,1,0]. The data received at the external outputs ext-Q[0], ext-Q[1], ext-Q[2], and ext-Q[3] are mapped to the columns of the external data map 140, one column at a time.

In a read operation, the row select circuit selects a row, such as x=0, and the column select circuit or one of the column decoder circuits selects a column, such as y=0, 1, 2, or 3. The selected column of y=0, 1, 2, or 3 selects one of the 4 inputs on each of the second plurality of multiplexers 110a-110d and/or one of the 4 inputs on each of the plurality of output multiplexers 114a-114d. The inputs of multiplexer 110a are selected in the [0,1,2,3] sequence, the inputs of multiplexer 110b are selected in the [1,0,3,2] sequence, the inputs of multiplexer 110c are selected in the [2,3,0,1] sequence, and the inputs of multiplexer 110d are selected in the [3,2,1,0] sequence. Also, the inputs of each of the plurality of output multiplexers 114a-114d are selected in the order [0,1,2,3]. In some embodiments, all the second plurality of multiplexers 110a-110d receive the same column select signal. In some embodiments, all the plurality of output multiplexers 114a-114d receive the same column select signal. In some embodiments, all the second plurality of multiplexers 110a-110d and all the plurality of output multiplexers 114a-114d receive the same column select signal. In some embodiments, the second plurality of multiplexers 110a-110d and the plurality of output multiplexers 114a-114d receive different column select signals at different times.

In reference to FIGS. 10 and 11, with the x-y address of the memory array 102 at x=0 and y=0, the data 00 is read from the memory cell 124a, received by the multiplexer 110a, and transmitted to the I/O terminal I/O[0] 108a and the internal output int-Q[0]. The data 00 is further received by the output multiplexer 114a, transmitted to the external output ext-Q[0], and mapped to the first column of the external data map 140 of FIG. 11. The data 10 is read from the memory cell 126b, received by the multiplexer 110b, and transmitted to the I/O terminal I/O[1] 108b and the internal output int-Q[1]. The data 10 is further received by the output multiplexer 114b, transmitted to the external output ext-Q[1], and mapped to the first column of the external data map 140 of FIG. 11. The data 20 is read from the memory cell 128c, received by the multiplexer 110c, and transmitted to the I/O terminal I/O[2] 108c and the internal output int-Q[2]. The data 20 is further received by the output multiplexer 114c, transmitted to the external output ext-Q[2], and mapped to the first column of the external data map 140 of FIG. 11. The data 30 is read from the memory cell 130d, received by the multiplexer 110d, and transmitted to the I/O terminal I/O[3] 108d and the internal output int-Q[3]. The data 30 is further received by the output multiplexer 114d, transmitted to the external output ext-Q[3], and mapped to the first column of the external data map 140 of FIG. 11. Thus, the data is transposed from the memory array 102 to the external outputs ext-Q[0], ext-Q[1], ext-Q[2] and the first column of data in the external data map 140.

With the x-y address of the memory array 102 at x=0 and y=1, the data 11 is read from the memory cell 126a, received by the multiplexer 110a, and transmitted to the I/O terminal I/O[0] 108a and the internal output int-Q[0]. The data 11 is further received by the output multiplexer 114a, transmitted to the external output ext-Q[0], and mapped to the second column of the external data map 140 of FIG. 11. The data 01 is read from the memory cell 124b, received by the multiplexer 110b, and transmitted to the I/O terminal I/O[1] 108b and the internal output int-Q[1]. The data 01 is further received by the output multiplexer 114b, transmitted to the external output ext-Q[1], and mapped to the second column of the external data map 140 of FIG. 11. The data 31 is read from the memory cell 130c, received by the multiplexer 110c, and transmitted to the I/O terminal I/O[2] 108c and the internal output int-Q[2]. The data 31 is further received by the output multiplexer 114c, transmitted to the external output ext-Q[2], and mapped to the second column of the external data map 140 of FIG. 11. The data 21 is read from the memory cell 128d, received by the multiplexer 110d, and transmitted to the I/O terminal I/O[3] 108d and the internal output int-Q[3]. The data 21 is further received by the output multiplexer 114d, transmitted to the external output ext-Q[3], and mapped to the second column of the external data map 140 of FIG. 11. Thus, the data is transposed from the memory array 102 to the external outputs ext-Q[0], ext-Q[1], ext-Q[2] and the second column of data in the external data map 140.

With the x-y address of the memory array 102 at x=0 and y=2, the data 22 is read from the memory cell 128a, received by the multiplexer 110a, and transmitted to the I/O terminal I/O[0] 108a and the internal output int-Q[0]. The data 22 is further received by the output multiplexer 114a, transmitted to the external output ext-Q[0], and mapped to the third column of the external data map 140 of FIG. 11. The data 32 is read from the memory cell 130b, received by the multiplexer 110b, and transmitted to the I/O terminal I/O[1] 108b and the internal output int-Q[1]. The data 32 is further received by the output multiplexer 114b, transmitted to the external output ext-Q[1], and mapped to the third column of the external data map 140 of FIG. 11. The data 02 is read from the memory cell 124c, received by the multiplexer 110c, and transmitted to the I/O terminal I/O[2] 108c and the internal output int-Q[2]. The data 02 is further received by the output multiplexer 114c, transmitted to the external output ext-Q[2], and mapped to the third column of the external data map 140 of FIG. 11. The data 12 is read from the memory cell 126d, received by the multiplexer 110d, and transmitted to the I/O terminal I/O[3] 108d and the internal output int-Q[3]. The data 12 is further received by the output multiplexer 114d, transmitted to the external output ext-Q[3], and mapped to the third column of the external data map 140 of FIG. 11. Thus, the data is transposed from the memory array 102 to the external outputs ext-Q[0], ext-Q[1], ext-Q[2] and the third column of data in the external data map 140.

With the x-y address of the memory array 102 at x=0 and y=3, the data 33 is read from the memory cell 130a, received by the multiplexer 110a, and transmitted to the I/O terminal I/O[0] 108a and the internal output int-Q[0]. The data 33 is further received by the output multiplexer 114a, transmitted to the external output ext-Q[0], and mapped to the fourth column of the external data map 140 of FIG. 11. The data 23 is read from the memory cell 128b, received by the multiplexer 110b, and transmitted to the I/O terminal I/O[1] 108b and the internal output int-Q[1]. The data 23 is further received by the output multiplexer 114b, transmitted to the external output ext-Q[1], and mapped to the fourth column of the external data map 140 of FIG. 11. The data 13 is read from the memory cell 126c, received by the multiplexer 110c, and transmitted to the I/O terminal I/O[2] 108c and the internal output int-Q[2]. The data 13 is further received by the output multiplexer 114c, transmitted to the external output ext-Q[2], and mapped to the fourth column of the external data map 140 of FIG. 11. The data 03 is read from the memory cell 124d, received by the multiplexer 110d, and transmitted to the I/O terminal I/O[3] 108d and the internal output int-Q[3]. The data 03 is further received by the output multiplexer 114d, transmitted to the external output ext-Q[3], and mapped to the fourth column of the external data map 140 of FIG. 11. Thus, the data is transposed from the memory array 102 to the external outputs ext-Q[0], ext-Q[1], ext-Q[2] and the fourth column of data in the external data map 140.

This process continues and is repeated for any number of rows, such as row x=1 and columns y=0, 1, 2, and 3.

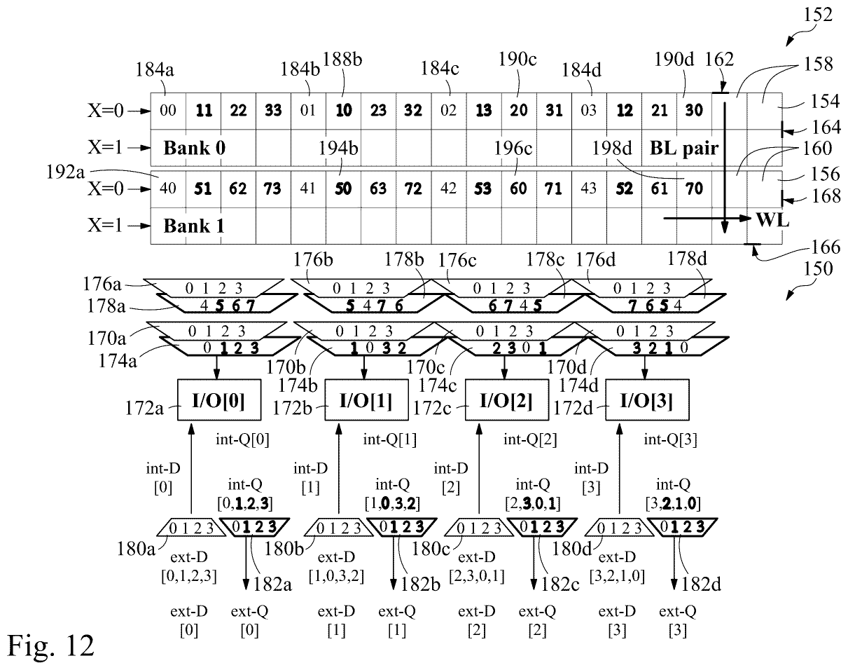

FIG. 12 is a diagram schematically illustrating control circuits 150 connected to a memory array 152 that includes a first memory bank (Bank 0) 154 and a second memory bank (Bank 1) 156, in accordance with some embodiments. The control circuits 150 are configured to write data into each of the first memory bank 154 and the second memory bank 156. Also, the control circuits 150 are configured to read data out of each of the first memory bank 154 and the second memory bank 156 in row-wise access operations and in column-wise access operations. In a first access operation, the data is read out of each of the first memory bank 154 and the second memory bank 156 in the “normal” row-wise sequence of the data. In a second access operation, the data is read out of each of the first memory bank 154 and the second memory bank 156 in the “transposed” column-wise sequence of the data. In some embodiments, the control circuits 150 are like the control circuits 52 shown in FIG. 3. In some embodiments, the memory array 152 is like the memory array 54 shown in FIG. 3.

The first memory bank 154 includes a first plurality of memory cells 158 that store data and the second memory bank 156 includes a second plurality of memory cells 160 that store data. The first plurality of memory cells 158 are situated in rows along the x-axis 162 and columns along the y-axis 164 of the first memory bank 154. The second plurality of memory cells 160 are situated in rows along the x-axis 166 and columns along the y-axis 168 of the second memory bank 156. Each of the first memory bank 154 and the second memory bank 156 includes BL pairs of BLs and BLBs, and WLs for accessing the memory cells 158 and 160 in the memory array 152.

Row select circuits, such as row select circuit 56, and column select circuits, such as column select circuit 58, are connected to the memory array 152 and configured to select the first memory bank 154 and the second memory bank 156 and the memory cells 158 and 160 in the rows and columns of the memory array 152 during read and write operations. In some embodiments, the row select circuits include bank select circuits for selecting the first memory bank 154 or the second memory bank 156. In some embodiments, the column select circuit includes one or more column decoder circuits, such as column decoder circuits 60, for selecting columns while reading data in the normal row-wise sequence of the data and reading data in the transposed column-wise sequence of the data. In some embodiments, the memory cells 158 and 160 are SRAM cells. In some embodiments, the memory cells 158 and 160 are like memory cell 80 of FIG. 4.

The control circuits 150 are connected to the memory array 152 by the BL pairs of BLs and BLBs and configured to write data into each of the first memory bank 154 and the second memory bank 156 and read data out of each of the first memory bank 154 and the second memory bank 156 of the memory array 152.

The control circuits 150 include a first plurality of multiplexers 170a-170d that retrieve data out of the first memory bank 154 and transmit the data to a plurality of I/O terminals 172a-172d in the first sequence of rows of data. Each of the first plurality of multiplexers 170a-170d is a 4 to 1 multiplexer having 4 inputs, such as 4 BL pair inputs (8 inputs), an output, and control inputs for selecting the input that is provided to the output of the multiplexer. The inputs of each of the first plurality of multiplexers 170a-170d are selected in a [0,1,2,3] sequence. The control circuits 150 further include a second plurality of multiplexers 174a-174d that retrieve the data out of the first memory bank 154 and transmit the data to the plurality of I/O terminals 172a-172d in the second sequence of columns of data that is transposed from the first sequence of rows of data. Each of the second plurality of multiplexers 174a-174d is a 4 to 1 multiplexer having 4 inputs, such as 4 BL pair inputs (8 inputs), an output, and control inputs for selecting the input that is provided to the output of the multiplexer. In some embodiments, the first plurality of multiplexers 170a-170d is like the first plurality of multiplexers 62 shown in FIG. 3. In some embodiments, the second plurality of multiplexers 174a-174d is like the second plurality of multiplexers 66 shown in FIG. 3. In some embodiments, the plurality of I/O terminals 172a-172d is like the plurality of I/O terminals 64 shown in FIG. 3. In other embodiments, each of the first plurality of multiplexers 170a-170d has more than 4 inputs, such as 8 or 16 inputs and one output. Also, in other embodiments, each of the second plurality of multiplexers 174a-174d has more than 4 inputs, such as 8 or 16 inputs and one output.

The control circuits 150 further include a third plurality of multiplexers 176a-176d that retrieve data out of the second memory bank 156 and transmit the data to the plurality of I/O terminals 172a-172d in the first sequence of rows of data. Each of the third plurality of multiplexers 176a-176d is a 4 to 1 multiplexer having 4 inputs, such as 4 BL pair inputs (8 inputs), an output, and control inputs for selecting the input that is provided to the output of the multiplexer. The inputs of each of the third plurality of multiplexers 176a-176d are selected in a [0,1,2,3] sequence. The control circuits 150 include a fourth plurality of multiplexers 178a-178d that retrieve the data out of the second memory bank 156 and transmit the data to the plurality of I/O terminals 172a-172d in the second sequence of columns of data that is transposed from the first sequence of rows of data. Each of the fourth plurality of multiplexers 178a-178d is a 4 to 1 multiplexer having 4 inputs, such as 4 BL pair inputs (8 inputs), an output, and control inputs for selecting the input that is provided to the output of the multiplexer. In some embodiments, the third plurality of multiplexers 176a-176d is like the first plurality of multiplexers 62 shown in FIG. 3. In some embodiments, the fourth plurality of multiplexers 178a-178d is like the second plurality of multiplexers 66 shown in FIG. 3. In other embodiments, each of the third plurality of multiplexers 176a-176d has more than 4 inputs, such as 8 or 16 inputs and one output. Also, in other embodiments, each of the fourth plurality of multiplexers 178a-178d has more than 4 inputs, such as 8 or 16 inputs and one output.

The control circuits 150 include a plurality of input multiplexers 180a-180d that receive data and transmit the data to the plurality of I/O terminals 172a-172d. Each of the plurality of input multiplexers 180a-180d is a 4 to 1 multiplexer having 4 inputs, an output, and control inputs for selecting the input that is provided to the output of the multiplexer. The inputs of each of the plurality of input multiplexers 180a-180d are selected in a [0,1,2,3] sequence. Also, the control circuits 150 include a plurality of output multiplexers 182a-182d that receive the data from the plurality of I/O terminals 172a-172d and the internal outputs int-Q and transmit the data to the external outputs ext-Q and hardware that is external to the control circuits 150 and/or the memory device. Each of the plurality of output multiplexers 182a-182d is a 4 to 1 multiplexer having 4 inputs, an output, and control inputs for selecting the input that is provided to the output of the multiplexer. The inputs of each of the plurality of output multiplexers 182a-182d are selected in a [0,1,2,3] sequence. In some embodiments, the plurality of input multiplexers 180a-180d are like the input multiplexers 68 shown in FIG. 3. In some embodiments, the plurality of output multiplexers 182a-182d are like the output multiplexers 70 shown in FIG. 3. In other embodiments, each of the plurality of input multiplexers 180a-180d has more than 4 inputs, such as 8 or 16 inputs and one output. Also, in other embodiments, each of the plurality of output multiplexers 182a-182d has more than 4 inputs, such as 8 or 16 inputs and one output. In other embodiments, the plurality of input multiplexers 180a-180d and/or the plurality of output multiplexers 182a-182d are external to the control circuits 150.

In a write operation, a row select circuit, such as the row select circuit 56, and a column select circuit, such as the column select circuit 58, decode addresses and select one of the memory banks 154 and 156 and the rows and columns of the memory cells 158 and 160 to be written. In some embodiments, the column select circuit includes one or more column decoder circuits, such as the column decoder circuits 60, for selecting inputs of the plurality of input multiplexers 180a-180d for writing data into the memory array 152.

To write data into one of the memory banks 154 and 156, data is transmitted to each of the external data inputs ext-D[0], ext-D[1], ext-D[2], and ext-D[3] and passed through a corresponding one of the plurality of input multiplexers 180a-180d to internal data inputs int-D[0], int-D[1], int-D[2], and int-D[3] and the plurality of I/O terminals 172a-172d, respectively. Each of the four inputs on each of the plurality of input multiplexers 180a-180d receives data. Input multiplexer 180a receives ext-D [0,1,2,3], input multiplexer 180b receives ext-D [1,0,3,2], input multiplexer 180c receives ext-D [2,3,0,1], and input multiplexer 180d receives ext-D [3,2,1,0]. The data that is written into the memory array 152 is provided externally, such as by another device or by a user.

In a write operation, the row select circuit selects one of the memory banks 154 and 156 and a row, such as x=0, and the column select circuit or one of the column decoder circuits selects a column, such as y=0, 1, 2, or 3. The selected column of y=0, 1, 2, or 3 selects one of the 4 inputs on each of the plurality of input multiplexers 180a-180d, which is provided to the output of the multiplexer. The inputs of each of the plurality of input multiplexers 180a-180d are selected in the order [0,1,2,3] and all the plurality of input multiplexers 180a-180d receive the same column select signal. The data is written into the memory cells 158 and 160 of the selected memory bank 154 and 156.

For example, with the first memory bank 154 selected and an x-y address of x=0 and y=0, the data 00 is provided to the external data input ext-D[] and written into memory cell 184a through the input multiplexer 180a and the I/O terminal 172a, the data 01 is provided to the external data input ext-D[1] and written into memory cell 184b through the input multiplexer 180b and the I/O terminal 172b, the data 02 is provided to the external data input ext-D[2] and written into memory cell 184c through the input multiplexer 180c and the I/O terminal 172c, and the data 03 is provided to the external data input ext-D[3] and written into the memory cell 184d through the input multiplexer 180d and the I/O terminal 172d. This can be continued for x=0 and the remaining columns y=1, 2, and 3 and for any number of rows, such as row x=1, and the columns y=0, 1, 2, and 3 for the first memory bank 154. Also, the second memory bank 156 is written in the same manner. In some embodiments, the first memory bank 154 and the second memory bank 156 are written like the memory array 102 shown in FIG. 7.

In a “normal” row-wise read operation of the memory array 152 by the control circuits 150, the data is read out of the memory array 152 in rows of data. A row select circuit, such as the row select circuit 56, and a column select circuit, such as the column select circuit 58, decode addresses and select one of the first memory bank 154 and the second memory bank 156 and the rows and columns of the memory cells 158 and 160 to be read. In some embodiments, the column select circuit includes one or more column decoder circuits, such as the column decoder circuits 60, for selecting inputs of the first plurality of multiplexers 170a-170d for the first memory bank 154, inputs of the third plurality of multiplexers 176a-176d for the second memory bank 156, and inputs of the plurality of output multiplexers 182a-182d for reading data out of the memory array 152.

To read data out of the first memory bank 154 in a “normal” row-wise read operation, the first plurality of multiplexers 170a-170d receive data from the first memory bank 154 and transmit the data to the plurality of I/O terminals 172a-172d and the internal outputs int-Q[0], int-Q[1] int-Q[2], and int-Q[3]. Next, the data is passed through the plurality of output multiplexers 182a-182d to the external outputs ext-Q[0], ext-Q[1], ext-Q[2], and ext-Q[3]. Output multiplexer 182a receives internal output data int-Q [0,1,2,3], output multiplexer 182b receives internal output data int-Q [1,0,3,2], output multiplexer 182c receives internal output data int-Q [2,3,0,1], and output multiplexer 182d receives internal output data int-Q [3,2,1,0]. The data received at the external outputs ext-Q[0], ext-Q[1], ext-Q[2], and ext-Q[3] are mapped to the rows of an external data map, one row at a time.

To read data out of the second memory bank 156 in a “normal” row-wise read operation, the third plurality of multiplexers 176a-176d receive data from the second memory bank 156 and transmit the data to the plurality of I/O terminals 172a-172d and the internal outputs int-Q[0], int-Q[1] int-Q[2], and int-Q[3]. Next, the data is passed through the plurality of output multiplexers 182a-182d to the external outputs ext-Q[0], ext-Q[1], ext-Q[2], and ext-Q[3]. Output multiplexer 182a receives internal output data int-Q [4,5,6,7], output multiplexer 182b receives internal output data int-Q [5,4,7,6], output multiplexer 182c receives internal output data int-Q [6,7,4,5], and output multiplexer 182d receives internal output data int-Q [7,6,5,4]. The data received at the external outputs ext-Q[0], ext-Q[1], ext-Q[2], and ext-Q[3] are mapped to the rows of an external data map, one row at a time.

In a “normal” row-wise read operation, the row select circuit selects one of the first memory bank 154 and the second memory bank 156 and a row, such as x=0, and the column select circuit or one of the column decoder circuits selects a column, such as y=0, 1, 2, or 3. The selected column of y=0, 1, 2, or 3 selects one of the 4 inputs on each of the first plurality of multiplexers 170a-170d or one of the 4 inputs on each of the third plurality of multiplexers 176a-176d, and one of the 4 inputs on each of the plurality of output multiplexers 182a-182d. The inputs of each of the first plurality of multiplexers 170a-170d are selected in the order [0,1,2,3], the inputs of each of the third plurality of multiplexers 176a-176d are selected in the order [0,1,2,3], and the inputs of each of the plurality of output multiplexers 182a-182d are selected in the order [0,1,2,3]. In some embodiments, all the first plurality of multiplexers 170a-170d receive the same column select signal. In some embodiments, all the third plurality of multiplexers 176a-176d receive the same column select signal. In some embodiments, all the plurality of output multiplexers 182a-182d receive the same column select signal. In some embodiments, all the first plurality of multiplexers 170a-170d and all the plurality of output multiplexers 182a-182d receive the same column select signal. In some embodiments, all the third plurality of multiplexers 176a-176d and all the plurality of output multiplexers 182a-182d receive the same column select signal. In some embodiments, the first plurality of multiplexers 170a-170d, the third plurality of multiplexers 176a-176d, and the plurality of output multiplexers 182a-182d receive different column select signals at different times.

For example, in a “normal” row-wise read operation, with the first memory bank 154 selected and with the x-y address at x=0 and y=0, the data 00 is read from the memory cell 184a, received by the multiplexer 170a, and transmitted to the I/O terminal I/O[0] 172a and the internal output int-Q[0]. The data 00 is further received by the output multiplexer 182a and transmitted to the external output ext-Q[0]. The data 01 is read from the memory cell 184b, received by the multiplexer 170b, and transmitted to the I/O terminal I/O[1] 172b and the internal output int-Q[1]. The data 01 is further received by the output multiplexer 182b and transmitted to the external output ext-Q[1]. The data 02 is read from the memory cell 184c, received by the multiplexer 170c, and transmitted to the I/O terminal I/O[2] 172c and the internal output int-Q[2]. The data 02 is further received by the output multiplexer 182c and transmitted to the external output ext-Q[2]. The data 03 is read from the memory cell 184d, received by the multiplexer 170d, and transmitted to the I/O terminal I/O[3] 172d and the internal output int-Q[3]. The data 03 is further received by the output multiplexer 182d and transmitted to the external output ext-Q[3]. The data received at the external outputs ext-Q[0], ext-Q[1], ext-Q[2], and ext-Q[3] are mapped to the first row of the external data map.

This can be continued for x=0 and the remaining columns y=1, 2, and 3 and for any number of rows, such as row x=1, and the columns =0, 1, 2, and 3 for the first memory bank 154. Also, in a “normal” row-wise read operation, the second memory bank 156 is read in the same manner, but with the second memory bank 156 selected and the third plurality of multiplexers 176a-176d. In some embodiments, the first memory bank 154 and the second memory bank 156 are read in a “normal”row-wise read operation like the memory array 102 shown in FIG. 9.

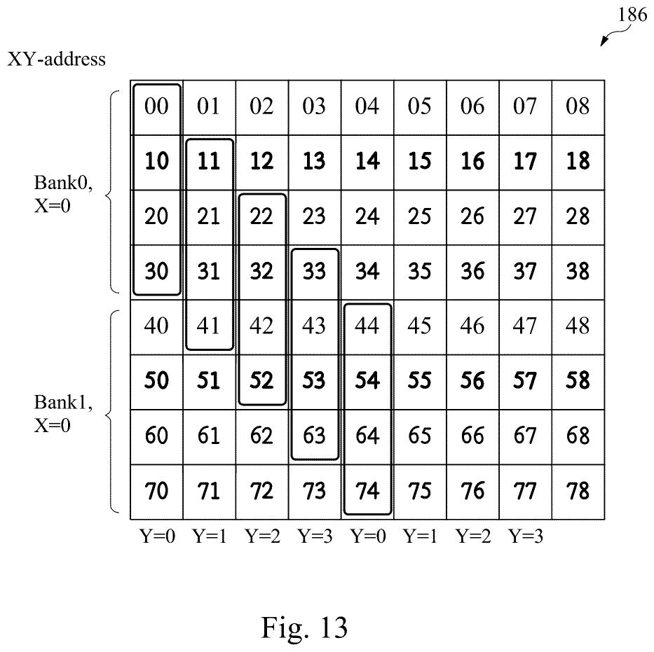

FIG. 13 is a diagram schematically illustrating an external data map 186 of data read from the first memory bank 154 and the second memory bank 156 in “transposed” column-wise read operations, in accordance with some embodiments.

Referring to FIGS. 12 and 13, in a “transposed” column-wise read operation of the memory array 152 by the control circuits 150, the data is read out of the memory array 152 in columns of data. A row select circuit, such as the row select circuit 56, and a column select circuit, such as the column select circuit 58, decode addresses and select one of the first memory bank 154 and the second memory bank 156 and the rows and columns of the memory cells 158 and 160 to be read. In some embodiments, the column select circuit includes one or more column decoder circuits, such as the column decoder circuits 60, for selecting inputs of the second plurality of multiplexers 174a-174d for the first memory bank 154, inputs of the fourth plurality of multiplexers 178a-178d for the second memory bank 156, and inputs of the plurality of output multiplexers 182a-182d for reading data out of the memory array 152.

For the first memory bank 154, the control circuits 150 include the second plurality of multiplexers 174a-174d that receive data from the first memory bank 154 and transmit the data to the plurality of I/O terminals 172a-172d. Each of the second plurality of multiplexers 174a-174d is a 4 to 1 multiplexer having 4 inputs, an output, and control inputs (not shown) for selecting the input that is provided to the output of the multiplexer. The inputs of multiplexer 174a are selected in a [0,1,2,3] sequence, the inputs of multiplexer 174b are selected in a [1,0,3,2] sequence, the inputs of multiplexer 174c are selected in a [2,3,0,1] sequence, and the inputs of multiplexer 174d are selected in a [3,2,1,0] sequence. In some embodiments, the second plurality of multiplexers 174a-174d is like the second plurality of multiplexers 66 shown in FIG. 3. In other embodiments, each of the second plurality of multiplexers 174a-174d has more than 4 inputs, such as 8 or 16 inputs, and one output.

For the second memory bank 156, the control circuits 150 include the fourth plurality of multiplexers 178a-178d that receive data from the second memory bank 156 and transmit the data to the plurality of I/O terminals 172a-172d. Each of the fourth plurality of multiplexers 178a-178d is a 4 to 1 multiplexer having 4 inputs, an output, and control inputs (not shown) for selecting the input that is provided to the output of the multiplexer. The inputs of multiplexer 178a are selected in a [4,5,6,7] sequence, the inputs of multiplexer 178b are selected in a [5,4,7,6] sequence, the inputs of multiplexer 178c are selected in a [6,7,4,5] sequence, and the inputs of multiplexer 178d are selected in a [7,6,5,4] sequence. In some embodiments, the fourth plurality of multiplexers 178a-178d is like the second plurality of multiplexers 66 shown in FIG. 3. In other embodiments, each of the fourth plurality of multiplexers 178a-178d has more than 4 inputs, such as 8 or 16 inputs, and one output.

The control circuits 150 further include the plurality of output multiplexers 182a-182d that receive data from the plurality of I/O terminals 172a-172d and the internal outputs int-Q. The plurality of output multiplexers 182a-182d transmit the data to the external outputs ext-Q. Each of the plurality of output multiplexers 182a-182d is a 4 to 1 multiplexer having 4 inputs, an output, and control inputs (not shown) for selecting the input that is provided to the output of the multiplexer. The inputs of each of the plurality of output multiplexers 182a-182d are selected in a [0,1,2,3] sequence. In some embodiments, the plurality of output multiplexers 182a-182d are like the output multiplexers 70 shown in FIG. 3. In other embodiments, each of the plurality of output multiplexers 182a-182d has more than 4 inputs, such as 8 or 16 inputs, and one output.

To read data out of the first memory bank 154 in a “transposed” column-wise read operation, the second plurality of multiplexers 174a-174d receive data from the first memory bank 154 and transmit the data to the plurality of I/O terminals 172a-172d and the internal outputs int-Q[0], int-Q[1] int-Q[2], and int-Q[3]. Next, the data is passed through the plurality of output multiplexers 182a-182d to the external outputs ext-Q[0], ext-Q[1], ext-Q[2], and ext-Q[3]. Output multiplexer 182a receives internal output data int-Q [0,1,2,3], output multiplexer 182b receives internal output data int-Q [1,0,3,2], output multiplexer 182c receives internal output data int-Q [2,3,0,1], and output multiplexer 182d receives internal output data int-Q [3,2,1,0]. The data received at the external outputs ext-Q[0], ext-Q[1], ext-Q[2], and ext-Q[3] are mapped to the columns of the external data map 186, one column at a time.

To read data out of the second memory bank 156 in a “transposed” column-wise read operation, the fourth plurality of multiplexers 178a-178d receive data from the second memory bank 156 and transmit the data to the plurality of I/O terminals 172a-172d and the internal outputs int-Q[0], int-Q[1] int-Q[2], and int-Q[3]. Next, the data is passed through the plurality of output multiplexers 182a-182d to the external outputs ext-Q[0], ext-Q[1], ext-Q[2], and ext-Q[3]. Output multiplexer 182a receives internal output data int-Q [4,5,6,7], output multiplexer 182b receives internal output data int-Q [5,4,7,6], output multiplexer 182c receives internal output data int-Q [6,7,4,5], and output multiplexer 182d receives internal output data int-Q [7,6,5,4]. The data received at the external outputs ext-Q[0], ext-Q[1], ext-Q[2], and ext-Q[3] are mapped to the columns of the external data map 186, one column at a time.

In a “transposed” column-wise read operation, the row select circuit selects one of the first memory bank 154 and the second memory bank 156 and a row, such as x=0, and the column select circuit or one of the column decoder circuits selects a column, such as y=0, 1, 2, or 3. If the first memory bank 154 is selected, the selected column of y=0, 1, 2, or 3 selects one of the 4 inputs on each of the second plurality of multiplexers 174a-174d and one of the 4 inputs on each of the plurality of output multiplexers 182a-182d. The inputs of multiplexer 174a are selected in the [0,1,2,3] sequence, the inputs of multiplexer 174b are selected in the [1,0,3,2] sequence, the inputs of multiplexer 174c are selected in the [2,3,0,1] sequence, and the inputs of multiplexer 174d are selected in the [3,2,1,0] sequence. Also, the inputs of each of the plurality of output multiplexers 182a-182d are selected in the order [0,1,2,3].

If the second memory bank 156 is selected, the selected column of y=0, 1, 2, or 3 selects one of the 4 inputs on each of the fourth plurality of multiplexers 178a-178d and one of the 4 inputs on each of the plurality of output multiplexers 182a-182d. The inputs of multiplexer 178a are selected in the [4,5,6,7] sequence, the inputs of multiplexer 178b are selected in the [5,4,7,6] sequence, the inputs of multiplexer 178c are selected in the [6,7,4,5] sequence, and the inputs of multiplexer 178d are selected in the [7,6,5,4] sequence. Also, the inputs of each of the plurality of output multiplexers 182a-182d are selected in the order [0,1,2,3].

In some embodiments, all the second plurality of multiplexers 174a-174d receive the same column select signal. In some embodiments, all the fourth plurality of multiplexers 178a-178d receive the same column select signal. In some embodiments, all the plurality of output multiplexers 182a-182d receive the same column select signal. In some embodiments, all the second plurality of multiplexers 174a-174d and all the plurality of output multiplexers 182a-182d receive the same column select signal. In some embodiments, all the fourth plurality of multiplexers 178a-178d and all the plurality of output multiplexers 182a-182d receive the same column select signal. In some embodiments, the second plurality of multiplexers 174a-174d, the fourth plurality of multiplexers 178a-178d, and the plurality of output multiplexers 182a-182d receive different column select signals at different times.

For example, in reference to FIGS. 12 and 13, in a “transposed” column-wise read operation with the first memory bank 154 selected and the x-y address at x=0 and y=0, the data 00 is read from the memory cell 184a, received by the multiplexer 174a, and transmitted to the I/O terminal I/O[0] 172a and the internal output int-Q[0]. The data 00 is further received by the output multiplexer 182a, transmitted to the external output ext-Q[0], and mapped to the first column of the external data map 186 of FIG. 13. The data 10 is read from the memory cell 188b, received by the multiplexer 174b, and transmitted to the I/O terminal I/O[1] 172b and the internal output int-Q[1]. The data 10 is further received by the output multiplexer 182b, transmitted to the external output ext-Q[1], and mapped to the first column of the external data map 186 of FIG. 13. The data 20 is read from the memory cell 190c, received by the multiplexer 174c, and transmitted to the I/O terminal I/O[2] 172c and the internal output int-Q[2]. The data 20 is further received by the output multiplexer 182c, transmitted to the external output ext-Q[2], and mapped to the first column of the external data map 186 of FIG. 13. The data 30 is read from the memory cell 190d, received by the multiplexer 174d, and transmitted to the I/O terminal I/O[3] 172d and the internal output int-Q[3]. The data 30 is further received by the output multiplexer 182d, transmitted to the external output ext-Q[3], and mapped to the first column of the external data map 186 of FIG. 13. Thus, the data is transposed from the first memory bank 154 to the external outputs ext-Q[0], ext-Q[1], ext-Q[2] and the first column of data in the external data map 186.

This can be continued for the first memory bank 154 for x=0 and the remaining columns y=1, 2, and 3 and for any number of rows, such as row x=1, and the columns y=0, 1, 2, and 3. Also, in a “transposed” column-wise read operation, the second memory bank 156 is read in the same manner, but with the second memory bank 156 selected and the fourth plurality of multiplexers 178a-178d. In some embodiments, the first memory bank 154 and the second memory bank 156 are read in “transposed” column-wise read operations like the memory array 102 shown in FIG. 10.

To continue mapping to the first column of data in the external data map 186 in a “transposed” column-wise read operation, the second memory bank 156 is selected with the x-y address at x =0 and y=0, the data 40 is read from the memory cell 192a, received by the multiplexer 178a, and transmitted to the I/O terminal I/O[0] 172a and the internal output int-Q[0]. The data 40 is further received by the output multiplexer 182a, transmitted to the external output ext-Q[0], and mapped to the first column of the external data map 186 of FIG. 13. The data 50 is read from the memory cell 194b, received by the multiplexer 178b, and transmitted to the I/O terminal I/O[1] 172b and the internal output int-Q[1]. The data 50 is further received by the output multiplexer 182b, transmitted to the external output ext-Q[1], and mapped to the first column of the external data map 186 of FIG. 13. The data 60 is read from the memory cell 196c, received by the multiplexer 178c, and transmitted to the I/O terminal I/O[2] 172c and the internal output int-Q[2]. The data 60 is further received by the output multiplexer 182c, transmitted to the external output ext-Q[2], and mapped to the first column of the external data map 186 of FIG. 13. The data 70 is read from the memory cell 198d, received by the multiplexer 178d, and transmitted to the I/O terminal I/O[3] 172d and the internal output int-Q[3]. The data 70 is further received by the output multiplexer 182d, transmitted to the external output ext-Q[3], and mapped to the first column of the external data map 186 of FIG. 13. Thus, the data is transposed from the second memory bank 156 of the memory array 102 to the external outputs ext-Q[0], ext-Q[1], ext-Q[2] and the first column of data in the external data map 186.

This can be continued for the second memory bank 156 for x=0 and the remaining columns y=1, 2, and 3 and for any number of rows, such as row x=1, and the columns y=0, 1, 2, and 3. Thus, the end user has access to columns of data in the external data map 186, including columns that are offset row-wise from one another.

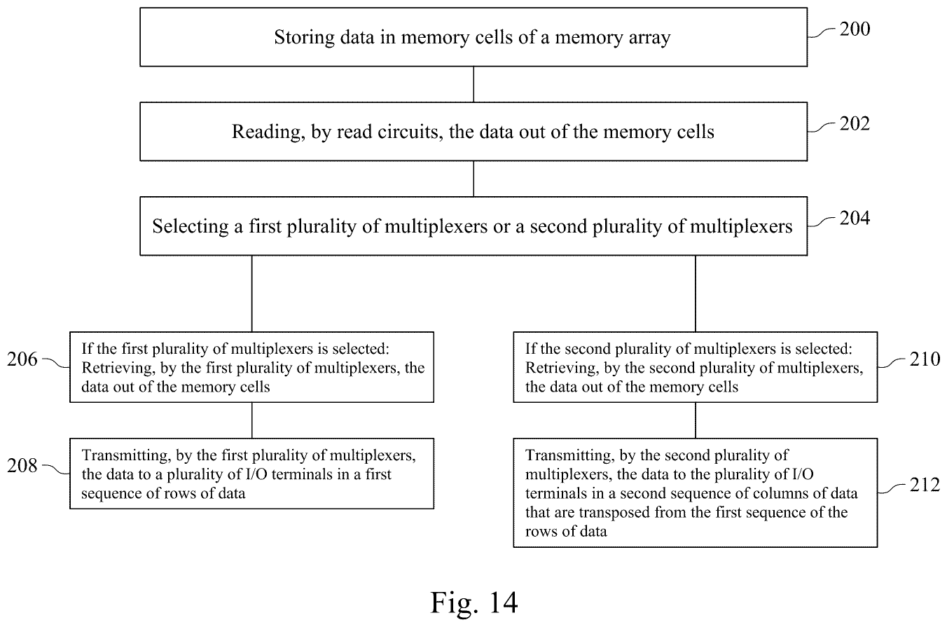

FIG. 14 is a diagram schematically illustrating a method of operating a memory device, in accordance with some embodiments. At 200, the method includes storing data in memory cells of a memory array. In some embodiments, the memory cells are like memory cells 104 shown in FIG. 5. In some embodiments, the memory cells are like memory cells 158 and 160 shown in FIG. 12. In some embodiments, the memory array is like the memory array 102 shown in FIG. 5. In some embodiments, the memory array is like the memory array 152 shown in FIG. 12.

At 202, the method includes reading, by read circuits, the data out of the memory cells. In some embodiments, the read circuits are like the read circuits 34 shown in FIGS. 1 and 2.

At 204, the method includes selecting a first plurality of multiplexers or a second plurality of multiplexers. In some embodiments, the first plurality of multiplexers is like the first plurality of multiplexers 106a-106d shown in FIG. 5. In some embodiments, the first plurality of multiplexers is like the first plurality of multiplexers 170a-170d shown in FIG. 12. In some embodiments, the first plurality of multiplexers is like the third plurality of multiplexers 176a-176d shown in FIG. 12. In some embodiments, the second plurality of multiplexers is like the second plurality of multiplexers 110a-110d shown in FIG. 5. In some embodiments, the second plurality of multiplexers is like the second plurality of multiplexers 174a-174d shown in FIG. 12. In some embodiments, the second plurality of multiplexers is like the fourth plurality of multiplexers 178a-178d shown in FIG. 12.

At 206, the method includes, if the first plurality of multiplexers is selected, retrieving, by the first plurality of multiplexers, the data out of the memory cells and, at 208, transmitting, by the first plurality of multiplexers, the data to a plurality of I/O terminals in a first sequence of rows of data.

In some embodiments, retrieving, by the first plurality of multiplexers, the data out of the memory cells, and transmitting, by the first plurality of multiplexers, the data to the plurality of I/O terminals in the first sequence of rows of data includes: retrieving the data out of the memory cells in the first sequence of the rows of data by a first multiplexer having 4 inputs selectively connected to the memory array and one output selectively connected to a first I/O terminal, by a second multiplexer having 4 inputs selectively connected to the memory array and one output selectively connected to a second I/O terminal, by a third multiplexer having 4 inputs selectively connected to the memory array and one output selectively connected to a third I/O terminal, and by a fourth multiplexer having 4 inputs selectively connected to the memory array and one output selectively connected to a fourth I/O terminal; and transmitting the first sequence of the rows of data by the first plurality of multiplexers to the first I/O terminal, the second I/O terminal, the third I/O terminal, and the fourth I/O terminal.

At 210, the method includes, if the second plurality of multiplexers is selected, retrieving, by the second plurality of multiplexers, the data out of the memory cells and, at 212, transmitting, by the second plurality of multiplexers, the data to the plurality of I/O terminals in a second sequence of columns of data that are transposed from the first sequence of the rows of data.

In some embodiments, retrieving, by the second plurality of multiplexers, the data out of the memory cells, and transmitting, by the second plurality of multiplexers, the data to the plurality of I/O terminals in a second sequence of columns of data includes: retrieving the data out of the memory cells in the second sequence of the columns of data by a fifth multiplexer having 4 inputs selectively connected to the memory array and one output selectively connected to the first I/O terminal, a sixth multiplexer having 4 inputs selectively connected to the memory array and one output selectively connected to the second I/O terminal, a seventh multiplexer having 4 inputs selectively connected to the memory array and one output selectively connected to the third I/O terminal, and an eighth multiplexer having 4 inputs selectively connected to the memory array and one output selectively connected to the fourth I/O terminal; and transmitting the second sequence of the columns of data by the second plurality of multiplexers to the first I/O terminal, the second I/O terminal, the third I/O terminal, and the fourth I/O terminal.

In some embodiments, retrieving, by the first plurality of multiplexers, the data out of the memory cells includes retrieving the data out of a first bank of memory cells, by the first plurality of multiplexers, in the first sequence, and retrieving, by the second plurality of multiplexers, the data out of the memory cells includes retrieving the data out of the first bank of memory cells, by the second plurality of multiplexers, in the second sequence.

In some embodiments, the method includes retrieving the data out of a second bank of memory cells by a third plurality of multiplexers in the first sequence and retrieving the data out of the second bank of memory cells by a fourth plurality of multiplexers in the second sequence.

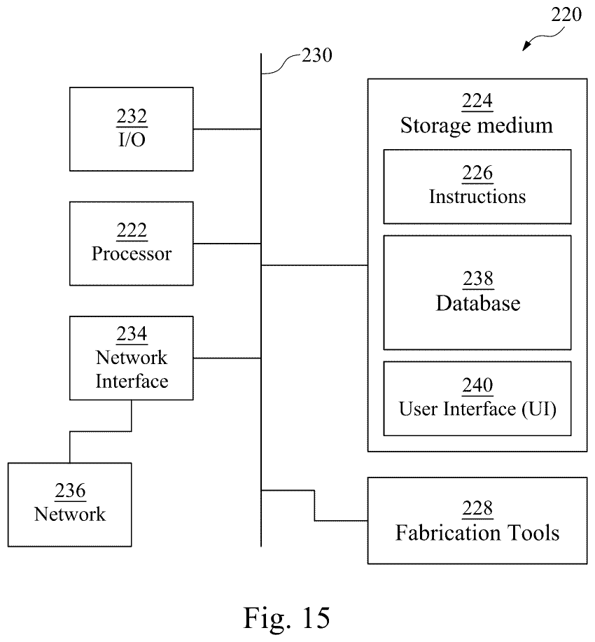

FIG. 15 is a block diagram schematically illustrating an example of a computer system 220 configured to provide the electronic devices, semiconductor devices, and methods of the current disclosure, in accordance with some embodiments. Some or all the design, layout, and manufacture of the semiconductor devices, also referred to as semiconductor circuits, can be performed by or with the aid of the computer system 220. Also, some or all the design, layout, and manufacture of the electronic devices can be performed by or with the aid of the computer system 220. In some embodiments, the computer system 220 includes an electronic design automation (EDA) system. In some embodiments, the semiconductor devices are ICs.

In some embodiments, the system 220 is a general-purpose computing device including a processor 222 and a non-transitory, computer-readable storage medium 224. The computer-readable storage medium 224 may be encoded with, e.g., store, computer program code such as executable instructions 226. Execution of the instructions 226 by the processor 222 provides (at least in part) a design tool that implements a portion or all the functions of the system 220, such as pre-layout simulations, post-layout simulations, routing, rerouting, and final layout for manufacturing. Further, fabrication tools 228 are included to further layout and physically implement the design and manufacture of the semiconductor devices. In some embodiments, execution of the instructions 226 by the processor 222 provides (at least in part) a design tool that implements a portion or all the functions of the system 220. In some embodiments, the system 220 includes a commercial router. In some embodiments, the system 220 includes an automatic place and route (APR) system.

The processor 222 is electrically coupled to the computer-readable storage medium 224 by a bus 230 and to an I/O interface 232 by the bus 230. A network interface 234 is also electrically connected to the processor 222 by the bus 230. The network interface 234 is connected to a network 236, so that the processor 222 and the computer-readable storage medium 224 can connect to external elements using the network 236. The processor 222 is configured to execute the computer program code or instructions 226 encoded in the computer-readable storage medium 224 to cause the system 220 to perform a portion or all the functions of the system 220, such as providing the semiconductor devices and methods of the current disclosure and other functions of the system 220. In some embodiments, the processor 222 is a central processing unit (CPU), a multi-processor, a distributed processing system, an application specific integrated circuit (ASIC), and/or a suitable processing unit.

In some embodiments, the computer-readable storage medium 224 is an electronic, magnetic, optical, electromagnetic, infrared, and/or semiconductor system or apparatus or device. For example, the computer-readable storage medium 224 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 224 can include a compact disk read only memory (CD-ROM), a compact disk read/write memory (CD-R/W), and/or a digital video disc (DVD).

In some embodiments, the computer-readable storage medium 224 stores computer program code or instructions 226 configured to cause the system 220 to perform a portion or all the functions of the system 220. In some embodiments, the computer-readable storage medium 224 also stores information which facilitates performing a portion or all the functions of the system 220. In some embodiments, the computer-readable storage medium 224 stores a database 238 that includes one or more of component libraries, digital circuit cell libraries, and databases.

The system 220 includes the I/O interface 232, which is coupled to external circuitry. In some embodiments, the I/O interface 232 includes a keyboard, keypad, mouse, trackball, trackpad, touchscreen, and/or cursor direction keys for communicating information and commands to the processor 222.

The network interface 234 is coupled to the processor 222 and allows the system 220 to communicate with the network 236, to which one or more other computer systems are connected. The network interface 234 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 220 can be performed in two or more systems that are like system 220.

The system 220 is configured to receive information through the I/O interface 232. The information received through the I/O interface 232 includes one or more of instructions, data, design rules, libraries of components and cells, and/or other parameters for processing by the processor 222. The information is transferred to the processor 222 by the bus 230. Also, the system 220 is configured to receive information related to a user interface (UI) through the I/O interface 232. This UI information can be stored in the computer-readable storage medium 224 as a UI 240.

In some embodiments, a portion or all the functions of the system 220 are implemented via a standalone software application for execution by a processor. In some embodiments, a portion or all the functions of the system 220 are implemented in a software application that is a part of an additional software application. In some embodiments, a portion or all the functions of the system 220 are implemented as a plug-in to a software application. In some embodiments, at least one of the functions of the system 220 is implemented as a software application that is a portion of an EDA tool. In some embodiments, a portion or all the functions of the system 220 are implemented as a software application that is used by the system 220. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 220 include fabrication tools 228 for implementing the manufacturing processes of the system 220. For example, based on the final layout, photolithographic masks may be generated, which are used to fabricate the semiconductor device by the fabrication tools 228.

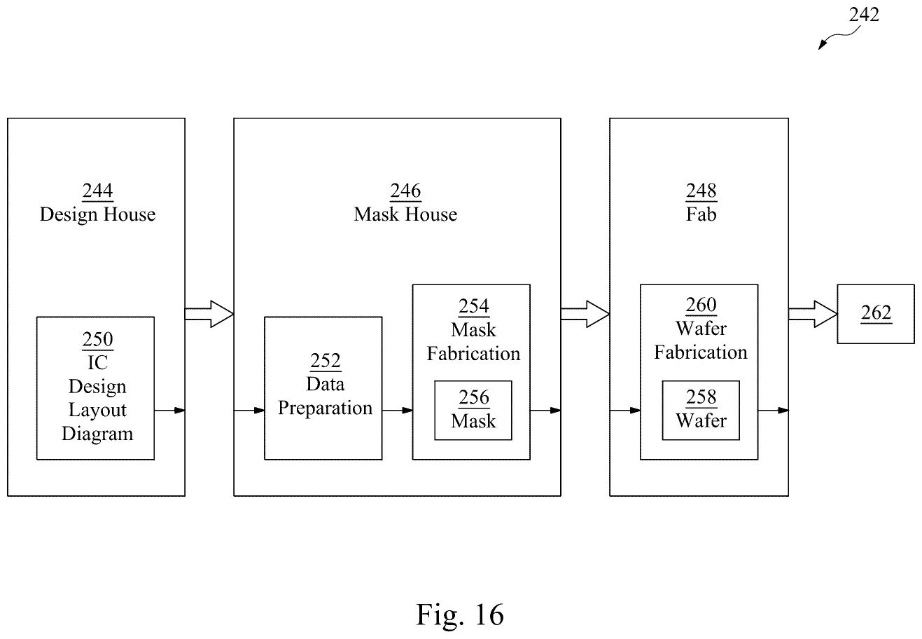

Further aspects of device fabrication are disclosed in conjunction with FIG. 16, which is a block diagram of a semiconductor device manufacturing system 242 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 242.

In FIG. 16, the semiconductor device manufacturing system 242 includes entities, such as a design house 244, a mask house 246, and a semiconductor device manufacturer/fabricator (“Fab”) 248, that interact with one another in the design, development, and manufacturing cycles and/or services related to manufacturing a semiconductor device, such as the semiconductor devices described herein. The entities in the system 242 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 244, the mask house 246, and the semiconductor device fab 248 are owned by a single larger company. In some embodiments, two or more of the design house 244, the mask house 246, and the semiconductor device fab 248 coexist in a common facility and use common resources.

The design house (or design team) 244 generates a semiconductor device design layout diagram 250. The semiconductor device design layout diagram 250 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 250 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 244 implements a design procedure to form a semiconductor device design layout diagram 250. The semiconductor device design layout diagram 250 is presented in one or more data files having information of the geometrical patterns. For example, semiconductor device design layout diagram 250 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 246 includes data preparation 252 and mask fabrication 254. The mask house 246 uses the semiconductor device design layout diagram 250 to manufacture one or more masks 256 to be used for fabricating the various layers of the semiconductor device or semiconductor structure. The mask house 246 performs mask data preparation 252, where the semiconductor device design layout diagram 250 is translated into a representative data file (RDF). The mask data preparation 252 provides the RDF to the mask fabrication 254. The mask fabrication 254 includes a mask writer that converts the RDF to an image on a substrate, such as a mask (reticle) 256 or a semiconductor wafer 258. The design layout diagram 250 is manipulated by the mask data preparation 252 to comply with characteristics of the mask writer and/or criteria of the semiconductor device fab 248. In FIG. 16, the mask data preparation 252 and the mask fabrication 254 are illustrated as separate elements. In some embodiments, the mask data preparation 252 and the mask fabrication 254 can be collectively referred to as mask data preparation.

In some embodiments, the mask data preparation 252 includes an optical proximity correction (OPC) which uses lithography enhancement techniques to compensate for image errors, such as those that can arise from diffraction, interference, other process effects and the like. The OPC adjusts the semiconductor device design layout diagram 250. In some embodiments, the mask data preparation 252 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 252 includes a mask rule checker (MRC) that checks the semiconductor device design layout diagram 250 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 250 to compensate for limitations during the mask fabrication 254, which may undo part of the modifications performed by OPC to meet mask creation rules.

In some embodiments, the mask data preparation 252 includes lithography process checking (LPC) that simulates processing that will be implemented by the semiconductor device fab 248. LPC simulates this processing based on the semiconductor device design layout diagram 250 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 250.

The above description of mask data preparation 252 has been simplified for the purposes of clarity. In some embodiments, data preparation 252 includes additional features such as a logic operation (LOP) to modify the semiconductor device design layout diagram 250 according to manufacturing rules. Additionally, the processes applied to the semiconductor device design layout diagram 250 during data preparation 252 may be executed in a variety of different orders.

After the mask data preparation 252 and during the mask fabrication 254, a mask 256 or a group of masks 256 are fabricated based on the modified semiconductor device design layout diagram 250. In some embodiments, the mask fabrication 254 includes performing one or more lithographic exposures based on the semiconductor device design layout diagram 250. In some embodiments, an electron-beam (e-beam) or a mechanism of multiple e-beams is used to form a pattern on a mask (photomask or reticle) 256 based on the modified semiconductor device design layout diagram 250. The mask 256 can be formed in various technologies. In some embodiments, the mask 256 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 256 includes a transparent substrate (e.g., fused quartz) and an opaque material (e.g., chromium) coated in the opaque regions of the binary mask. In another example, the mask 256 is formed using a phase shift technology. In a phase shift mask (PSM) version of the mask 256, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 254 is used in a variety of processes. For example, such a mask(s) is used in an ion implantation process to form various doped regions in the semiconductor wafer 258, in an etching process to form various etching regions in the semiconductor wafer 258, and/or in other suitable processes.

The semiconductor device fab 248 includes wafer fabrication 260. The semiconductor device fab 248 is a semiconductor device fabrication business that includes one or more manufacturing facilities for the fabrication of a variety of different semiconductor device products. In some embodiments, the semiconductor device fab 248 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 248 uses the mask(s) 256 fabricated by the mask house 246 to fabricate the semiconductor structures or semiconductor devices 262 of the current disclosure. Thus, the semiconductor device fab 248 at least indirectly uses the semiconductor device design layout diagram 250 to fabricate the semiconductor structures or semiconductor devices 262 of the current disclosure. Also, the semiconductor wafer 258 includes a silicon substrate or other proper substrate having material layers formed thereon, and the semiconductor wafer 258 further includes one or more of various doped regions, dielectric features, multilevel interconnects, and the like (formed at subsequent manufacturing steps). In some embodiments, the semiconductor wafer 258 is fabricated by the semiconductor device fab 248 using the mask(s) 256 to form the semiconductor structures or semiconductor devices 262 of the current disclosure. In some embodiments, the semiconductor device fabrication includes performing one or more lithographic exposures based at least indirectly on the semiconductor device design layout diagram 250.

Disclosed embodiments provide a memory device configured to read data from a memory array in a “normal” row-wise access of the data and in a “transposed” column-wise access of the data. The disclosed embodiments include a first plurality of multiplexers that retrieve data out of memory cells and transmit the data to a plurality of I/O terminals in a first sequence of rows of data, and a second plurality of multiplexers that retrieve the data out of the memory cells and transmit the data to the plurality of I/O terminals in a second sequence of columns of data that are transposed from the first sequence of rows of data.

Disclosed embodiments further provide a method of operating a memory device that includes storing data in memory cells of a memory array, reading, by read circuits, the data out of the memory cells, and selecting a first plurality of multiplexers or a second plurality of multiplexers. If the first plurality of multiplexers is selected the method includes retrieving the data out of the memory cells and transmitting the data to a plurality of I/O terminals in a first sequence of rows of data. If the second plurality of multiplexers is selected the method includes retrieving the data out of the memory cells and transmitting the data to the plurality of I/O terminals in a second sequence of columns of data that are transposed from the first sequence of the rows of data.

Advantages of the disclosed embodiments include data rearrangement is achieved by the memory device without extra buffers or multiple macros, the memory device is adaptive to different matrix computations, such as for AI applications, and the disclosed embodiments reduce power consumption, reduce latency, and reduce the area or size of the memory device.

In accordance with some embodiments, a device includes a memory array configured to store data in memory cells, read circuits configured to read the data out of the memory cells, and a plurality of I/O terminals. A first plurality of multiplexers is configured to retrieve the data out of the memory cells and transmit the data to the plurality of I/O terminals in a first sequence of rows of data, and a second plurality of multiplexers is configured to retrieve the data out of the memory cells and transmit the data to the plurality of I/O terminals in a second sequence of columns of data that are transposed from the first sequence of rows of data.

In accordance with further embodiments, a device includes a memory array configured to store data in memory cells, read circuits configured to read the data out of the memory cells, and a plurality of I/O terminals that include a first I/O terminal and a second I/O terminal. A first plurality of multiplexers includes a first multiplexer having first inputs selectively connected to the memory array and a first output selectively connected to the first I/O terminal and a second multiplexer having second inputs selectively connected to the memory array and a second output selectively connected to the second I/O terminal. The first multiplexer and the second multiplexer are configured to transmit rows of data to the first I/O terminal and the second I/O terminal. A second plurality of multiplexers includes a third multiplexer having third inputs selectively connected to the memory array and a third output selectively connected to the first I/O terminal and a fourth multiplexer having fourth inputs selectively connected to the memory array and a fourth output selectively connected to the second I/O terminal. The third multiplexer and the fourth multiplexer are configured to transmit columns of data to the first I/O terminal and the second I/O terminal, wherein the columns of data are transposed from the rows of data.

In accordance with still further disclosed aspects, a method of operating a memory device includes storing data in memory cells of a memory array, reading, by read circuits, the data out of the memory cells, and selecting a first plurality of multiplexers or a second plurality of multiplexers. If the first plurality of multiplexers is selected the method includes retrieving, by the first plurality of multiplexers, the data out of the memory cells and transmitting, by the first plurality of multiplexers, the data to a plurality of I/O terminals in a first sequence of rows of data. If the second plurality of multiplexers is selected the method includes retrieving, by the second plurality of multiplexers, the data out of the memory cells and transmitting, by the second plurality of multiplexers, the data to the plurality of I/O terminals in a second sequence of columns of data that are transposed from the first sequence of the rows of data.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device, comprising:
a memory array configured to store data in memory cells;
read circuits configured to read the data out of the memory cells;
a plurality of input/output (I/O) terminals;
a first plurality of multiplexers configured to retrieve the data out of the memory cells and transmit the data to the plurality of I/O terminals in a first sequence of rows of data; and
a second plurality of multiplexers configured to retrieve the data out of the memory cells and transmit the data to the plurality of I/O terminals in a second sequence of columns of data that is transposed from the first sequence of rows of data.

2. The device of claim 1, wherein the plurality of I/O terminals includes an I/O terminal I/O[0], an I/O terminal I/O[1], an I/O terminal I/O[2], and an I/O terminal I/O[3].

3. The device of claim 2, wherein the first plurality of multiplexers includes a first multiplexer having inputs selectively connected to the memory array and one output selectively connected to the I/O terminal I/O[0], a second multiplexer having inputs selectively connected to the memory array and one output selectively connected to the I/O terminal I/O[1], a third multiplexer having inputs selectively connected to the memory array and one output selectively connected to the I/O terminal I/O[2], and a fourth multiplexer having inputs selectively connected to the memory array and one output selectively connected to the I/O terminal I/O[3].

4. The device of claim 3, wherein the second plurality of multiplexers includes a fifth multiplexer having inputs selectively connected to the memory array and one output selectively connected to the I/O terminal I/O[0], a sixth multiplexer having inputs selectively connected to the memory array and one output selectively connected to the I/O terminal I/O[1], a seventh multiplexer having inputs selectively connected to the memory array and one output selectively connected to the I/O terminal I/O[2], and an eighth multiplexer having inputs selectively connected to the memory array and one output selectively connected to the I/O terminal I/O[3].

5. The device of claim 1, wherein the memory array includes at least two banks of memory cells, wherein:
a first bank of memory cells is selectively connected to the first plurality of multiplexers and the second plurality of multiplexers; and
a second bank of memory cells is selectively connected to a third plurality of multiplexers and a fourth plurality of multiplexers.

6. The device of claim 5, wherein the first plurality of multiplexers is configured to retrieve the data out of the first bank of memory cells in the first sequence of rows of data and transmit the data to the plurality of I/O terminals in the first sequence of rows of data, and the second plurality of multiplexers is configured to retrieve the data out of the first bank of memory cells in the second sequence of columns of data and transmit the data to the plurality of I/O terminals in the second sequence of columns of data.

7. The device of claim 5, wherein the third plurality of multiplexers is configured to retrieve the data out of the second bank of memory cells in the first sequence of rows of data and transmit the data to the plurality of I/O terminals in the first sequence of rows of data, and the fourth plurality of multiplexers is configured to retrieve the data out of the second bank of memory cells in the second sequence of columns of data and transmit the data to the plurality of I/O terminals in the second sequence of columns of data.

8. The device of claim 1, comprising a plurality of input multiplexers configured to receive external data and selectively provide an input multiplexer output to the plurality of I/O terminals.

9. The device of claim 1, comprising a plurality of output multiplexers configured to receive the data from the plurality of I/O terminals and selectively provide an output multiplexer output to an external output.

10. The device of claim 1, wherein the memory array is an SRAM memory array.

11. A device, comprising:
a memory array configured to store data in memory cells;
read circuits configured to read the data out of the memory cells;
a plurality of input/output (I/O) terminals that include a first I/O terminal and a second I/O terminal;
a first plurality of multiplexers that includes a first multiplexer having first inputs selectively connected to the memory array and a first output selectively connected to the first I/O terminal and a second multiplexer having second inputs selectively connected to the memory array and a second output selectively connected to the
second I/O terminal, the first multiplexer and the second multiplexer configured to transmit rows of data to the first I/O terminal and the second I/O terminal; and
a second plurality of multiplexers that includes a third multiplexer having third inputs selectively connected to the memory array and a third output selectively connected to the first I/O terminal and a fourth multiplexer having fourth inputs selectively connected to the memory array and a fourth output selectively connected to the second I/O terminal, the third multiplexer and the fourth multiplexer configured to transmit columns of data to the first I/O terminal and the second I/O terminal, wherein the columns of data are transposed from the rows of data.

12. The device of claim 11, wherein the memory array includes at least two banks of memory cells, wherein:
a first bank of memory cells is selectively connected to the first plurality of multiplexers and the second plurality of multiplexers; and
a second bank of memory cells is selectively connected to a third plurality of multiplexers and a fourth plurality of multiplexers.

13. The device of claim 12, wherein the first plurality of multiplexers is configured to transmit the rows of data to the first I/O terminal and the second I/O terminal out of the first bank of memory cells, and the second plurality of multiplexers is configured to transmit the columns of data to the first I/O terminal and the second I/O terminal out of the first bank of memory cells.

14. The device of claim 12, wherein the third plurality of multiplexers is configured to transmit the rows of data to the first I/O terminal and the second I/O terminal out of the second bank of memory cells, and the fourth plurality of multiplexers is configured to transmit the columns of data to the first I/O terminal and the second I/O terminal out of the second bank of memory cells.

15. The device of claim 11, comprising a plurality of input multiplexers configured to receive external data and selectively transmit an input multiplexer output to the plurality of I/O terminals, and a plurality of output multiplexers configured to receive the data from the plurality of I/O terminals and selectively transmit an output multiplexer output to an external output.

16. A method of operating a memory device, the method comprising:
storing data in memory cells of a memory array;
reading, by read circuits, the data out of the memory cells;
selecting a first plurality of multiplexers or a second plurality of multiplexers,
wherein if the first plurality of multiplexers is selected:
retrieving, by the first plurality of multiplexers, the data out of the memory cells; and
transmitting, by the first plurality of multiplexers, the data to a plurality of I/O terminals in a first sequence of rows of data; and
wherein if the second plurality of multiplexers is selected:
retrieving, by the second plurality of multiplexers, the data out of the memory cells; and
transmitting, by the second plurality of multiplexers, the data to the plurality of I/O terminals in a second sequence of columns of data that are transposed from the first sequence of the rows of data.

17. The method of claim 16, wherein retrieving, by the first plurality of multiplexers, the data out of the memory cells, and transmitting, by the first plurality of multiplexers, the data to the plurality of I/O terminals in the first sequence of rows of data includes:
retrieving the data out of the memory cells in the first sequence of the rows of data by a first multiplexer having 4 inputs selectively connected to the memory array and one output selectively connected to a first I/O terminal, by a second multiplexer having 4 inputs selectively connected to the memory array and one output selectively connected to a second I/O terminal, by a third multiplexer having 4 inputs selectively connected to the memory array and one output selectively connected to a third I/O terminal, and by a fourth multiplexer having 4 inputs selectively connected to the memory array and one output selectively connected to a fourth I/O terminal; and
transmitting the data by the first plurality of multiplexers to the first I/O terminal, the second I/O terminal, the third I/O terminal, and the fourth I/O terminal in the first sequence of the rows of data.

18. The method of claim 16, wherein retrieving, by the second plurality of multiplexers, the data out of the memory cells, and transmitting, by the second plurality of multiplexers, the data to the plurality of I/O terminals in a second sequence of columns of data includes:
retrieving the data out of the memory cells in the second sequence of the columns of data by a fifth multiplexer having 4 inputs selectively connected to the memory array and one output selectively connected to a the first I/O terminal, a sixth multiplexer having 4 inputs selectively connected to the memory array and one output selectively connected to a the second I/O terminal, a seventh multiplexer having 4 inputs selectively connected to the memory array and one output selectively connected to a third I/O terminal, and an eighth multiplexer having 4 inputs selectively connected to the memory array and one output selectively connected to a fourth I/O terminal; and
transmitting the data by the second plurality of multiplexers to the first I/O terminal, the second I/O terminal, the third I/O terminal, and the fourth I/O terminal in the second sequence of the columns of data.

19. The method of claim 16, wherein retrieving, by the first plurality of multiplexers, the data out of the memory cells includes retrieving the data out of a first bank of memory cells, by the first plurality of multiplexers, in the first sequence of the rows of data, and retrieving, by the second plurality of multiplexers, the data out of the memory cells includes retrieving the data out of the first bank of memory cells, by the second plurality of multiplexers, in the second sequence of the columns of data.

20. The method of claim 16, comprising retrieving the data out of a second bank of memory cells by a third plurality of multiplexers in the first sequence of the rows of data, and retrieving the data out of the second bank of memory cells by a fourth plurality of multiplexers in the second sequence of the columns of data.
